(19) United States
(12) Patent Application Publication
(10) Pub. No.: US 2024/0276721 A1
(43) Pub. Date: Aug. 15, 2024

(54) SEMICONDUCTOR MEMORY DEVICE

(71) Applicant: Kioxia Corporation, Tokyo (JP)

(72) Inventors: Kohei DATE, Yokkaichi (JP); Kenji AOYAMA, Yokohama (JP); Keisuke SUDA, Yokkaichi (JP); Minami TANAKA, Yokkaichi (JP); Satoshi NAGASHIMA, Yokkaichi (JP)

(73) Assignee: Kioxia Corporation, Tokyo (JP)

(21) Appl. No.: 18/439,898

(22) Filed: Feb. 13, 2024

(30) Foreign Application Priority Data
Feb. 14, 2023 (JP) 2023-020952

(51) Int. Cl. H10B 43/27; H10B 43/10

(52) U.S. Cl. CPC H10B 43/27; H10B 43/10

(57) ABSTRACT

According to one embodiment, a semiconductor memory device includes a plurality of conductor layers including a first conductor layer as an uppermost layer; a plurality of memory pillars penetrating the conductor layers; and a member that includes a first portion extending in the conductor layers and a plurality of second portions RT provided apart from each other on the uppermost layer side of the conductor layers, and divides the conductor layers in a direction in a substrate surface; wherein a lower surface of the second portion is located below an upper surface of the first conductor layer, and an upper surface of the second portion is wider in a width in the direction, than the lower surface of the second portion and than the first portion.

### CROSS-REFERENCE TO RELATED APPLICATIONS

This application is based upon and claims the benefit of priority from Japanese Patent Application No. 2023-020952, filed Feb. 14, 2023, the entire contents of which are incorporated herein by reference.

### FIELD

Embodiments described herein relate generally to a semiconductor memory device.

### BACKGROUND

A NAND flash memory has been known as a semiconductor memory device capable of storing data in a nonvolatile manner. In the NAND flash memory, a three-dimensional memory structure is adopted for high integration and large capacity.

### BRIEF DESCRIPTION OF DRAWINGS

FIG. 1 is a block diagram illustrating an example of a configuration of a memory system including a semiconductor memory device according to a first embodiment.

FIG. 2 is a circuit diagram illustrating an example of a circuit configuration of a memory cell array included in the semiconductor memory device according to the first embodiment.

FIG. 3 is a plan view illustrating an example of a planar layout of a memory cell array included in the semiconductor memory device according to the first embodiment.

FIG. 4 is a plan view illustrating an example of a planar layout of the memory cell array included in the semiconductor memory device according to the first embodiment.

FIG. 5 is a cross-sectional view taken along line V-V of FIG. 4, illustrating an example of a cross-sectional structure in a YZ plane of the memory cell array included in the semiconductor memory device according to the first embodiment.

FIG. 6 is a cross-sectional view illustrating an example of a cross-sectional structure in the YZ plane of the memory cell array included in the semiconductor memory device according to the first embodiment.

FIG. 7 is a cross-sectional view taken along line VII-VII of FIG. 5, illustrating an example of a cross-sectional structure in an XY plane of the memory cell array included in the semiconductor memory device according to the first embodiment.

FIG. 8 is a cross-sectional view taken along line VIII-VIII in FIG. 4, illustrating an example of a cross-sectional structure in an XZ plane of the memory cell array included in the semiconductor memory device according to the first embodiment.

FIG. 9 is a cross-sectional view taken along line IX-IX of FIG. 5, illustrating an example of a cross-sectional structure of a memory pillar of the memory cell array included in the semiconductor memory device according to the first embodiment.

FIG. 10 is a flowchart illustrating an example of a method for manufacturing the semiconductor memory device according to the first embodiment.

FIG. 11 is a cross-sectional view illustrating an example of the method for manufacturing the semiconductor memory device according to the first embodiment.

FIG. 12 is a cross-sectional view illustrating an example of the method for manufacturing the semiconductor memory device according to the first embodiment.

FIG. 13 is a cross-sectional view illustrating an example of the method for manufacturing the semiconductor memory device according to the first embodiment.

FIG. 14 is a cross-sectional view illustrating an example of the method for manufacturing the semiconductor memory device according to the first embodiment.

FIG. 15 is a plan view illustrating an example of the method for manufacturing the semiconductor memory device according to the first embodiment.

FIG. 16 is a cross-sectional view illustrating an example of the method for manufacturing the semiconductor memory device according to the first embodiment.

FIG. 17 is a cross-sectional view illustrating an example of the method for manufacturing the semiconductor memory device according to the first embodiment.

FIG. 18 is a cross-sectional view illustrating an example of the method for manufacturing the semiconductor memory device according to the first embodiment.

FIG. 19 is a cross-sectional view illustrating an example of the method for manufacturing the semiconductor memory device according to the first embodiment.

FIG. 20 is a cross-sectional view illustrating an example of the method for manufacturing the semiconductor memory device according to the first embodiment.

FIG. 21 is a cross-sectional view illustrating an example of the method for manufacturing the semiconductor memory device according to the first embodiment.

FIG. 22 is a cross-sectional view illustrating an example of the method for manufacturing the semiconductor memory device according to the first embodiment.

FIG. 23 is a cross-sectional view illustrating an example of the method for manufacturing the semiconductor memory device according to the first embodiment.

FIG. 24 is a cross-sectional view illustrating an example of the method for manufacturing the semiconductor memory device according to the first embodiment.

FIG. 25 is a cross-sectional view illustrating an example of the method for manufacturing the semiconductor memory device according to the first embodiment.

FIG. 26 is a cross-sectional view illustrating an example of the method for manufacturing the semiconductor memory device according to the first embodiment.

FIG. 27 is a cross-sectional view illustrating an example of a cross-sectional structure in a YZ plane of a memory cell array included in a semiconductor memory device according to a first modification of the first embodiment.

FIG. 28 is a cross-sectional view taken along line XXVIII-XXVIII of FIG. 27, illustrating an example of a cross-sectional structure of a memory pillar of the memory cell array included in the semiconductor memory device according to the first modification of the first embodiment.

FIG. 29 is a cross-sectional view illustrating an example of a cross-sectional structure in a YZ plane of a memory cell array included in a semiconductor memory device according to a second modification of the first embodiment.

FIG. 30 is a cross-sectional view illustrating an example of the cross-sectional structure in the YZ plane of the memory cell array included in the semiconductor memory device according to the second modification of the first embodiment.

FIG. 31 is a cross-sectional view illustrating an example of a cross-sectional structure in a YZ plane of a memory cell array included in a semiconductor memory device according to a third modification of the first embodiment.

FIG. 32 is a plan view illustrating an example of a planar layout of a memory cell array included in a semiconductor memory device according to a fourth modification of the first embodiment.

FIG. 33 is a cross-sectional view taken along line XXXIII-XXXIII of FIG. 32, illustrating an example of a cross-sectional structure in a YZ plane of the memory cell array included in the semiconductor memory device according to the fourth modification of the first embodiment.

FIG. 34 is a cross-sectional view illustrating an example of a cross-sectional structure in a YZ plane of a memory cell array included in a semiconductor memory device according to a second embodiment.

FIG. 35 is a cross-sectional view illustrating an example of a cross-sectional structure in an XZ plane of the memory cell array included in the semiconductor memory device according to the second embodiment.

FIG. 36 is a flowchart illustrating an example of a method for manufacturing the semiconductor memory device according to the second embodiment.

FIG. 37 is a cross-sectional view illustrating an example of the method for manufacturing the semiconductor memory device according to the second embodiment.

FIG. 38 is a cross-sectional view illustrating an example of the method for manufacturing the semiconductor memory device according to the second embodiment.

FIG. 39 is a cross-sectional view illustrating an example of the method for manufacturing the semiconductor memory device according to the second embodiment.

FIG. 40 is a cross-sectional view illustrating an example of the method for manufacturing the semiconductor memory device according to the second embodiment.

FIG. 41 is a cross-sectional view illustrating an example of a cross-sectional structure in a YZ plane of a memory cell array included in a semiconductor memory device according to a modification of the second embodiment.

FIG. 42 is a cross-sectional view illustrating an example of a cross-sectional structure in a YZ plane of a memory cell array included in a semiconductor memory device according to another example.

FIG. 43 is a cross-sectional view illustrating an example of a cross-sectional structure in a YZ plane of a memory cell array included in a semiconductor memory device according to another example.

### DETAILED DESCRIPTION

In general, according to one embodiment, a semiconductor memory device includes a plurality of conductor layers provided apart from each other in a first direction perpendicular to a substrate surface and including a first conductor layer as an uppermost layer; a plurality of memory pillars penetrating the conductor layers and extending in the first direction; and a member that includes a first portion extending in a second direction in the substrate surface in the conductor layers and a plurality of second portions provided apart from each other in the second direction on the uppermost layer side of the conductor layers, and divides the conductor layers in a third direction orthogonal to the second direction in the substrate surface; wherein a lower surface of each of the second portions is located below an upper surface of the first conductor layer, and an upper surface of each of the second portions is wider in a width of the member in the third direction, than the lower surface of each of the second portions and than the first portion.

Embodiments will be described with reference to the drawings. Note that dimensions and ratios of the drawings are not necessarily the same as actual ones. In the following description, components having substantially the same functions and configurations are denoted by the same reference numerals. Furthermore, in a case where elements having similar configurations are particularly distinguished from each other, different characters or numbers may be added to the end of the same reference numeral.

### 1 First Embodiment

Hereinafter, a semiconductor memory device according to a first embodiment will be described.

### 1.1 Configuration

A configuration of the semiconductor memory device according to the first embodiment will be described.

### 1.1.1 Memory System

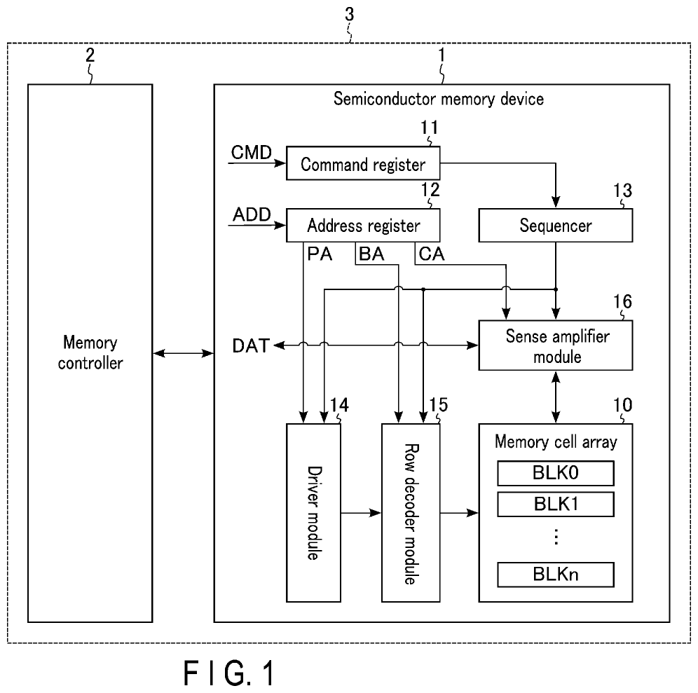

First, a configuration example of a memory system will be described with reference to FIG. 1. FIG. 1 is a block diagram illustrating an example of a configuration of a memory system including the semiconductor memory device according to the first embodiment.

A memory system 3 is, for example, a solid state drive (SSD) or an SD™ card. The memory system 3 is coupled to, for example, an external host device (not illustrated). The memory system 3 stores data from the host device. In addition, the memory system 3 reads data to the host device.

The memory system 3 includes a semiconductor memory device 1 and a memory controller 2.

The semiconductor memory device 1 is, for example, a NAND flash memory. The semiconductor memory device 1 stores data in a nonvolatile manner. Hereinafter, a case where the semiconductor memory device 1 is a NAND flash memory will be described as an example.

The memory controller 2 includes, for example, an integrated circuit such as a system-on-a-chip (SoC). The memory controller 2 writes data to the semiconductor memory device 1 based on, for example, a request from the host device. In addition, the memory controller 2 reads data from the semiconductor memory device 1, for example, on the basis of a request from the host device. In addition, the memory controller 2 transmits data read from the semiconductor memory device 1 to the host device.

Communication between the semiconductor memory device 1 and the memory controller 2 conforms to, for example, a single data rate (SDR) interface, a toggle double data rate (DDR) interface, or an open NAND flash interface (ONFI).

### 1.1.2 Semiconductor Memory Device

Subsequently, an internal configuration of the semiconductor memory device 1 will be described with reference to FIG. 1. The semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). The block BLK is a set of a plurality of memory cells capable of storing data in a nonvolatile manner. The block BLK is used, for example, as a data erasing unit. A plurality of bit lines and a plurality of word lines are provided in the memory cell array 10. One memory cell is associated with, for example, one bit line and one word line.

The command register 11 holds a command CMD received by the semiconductor memory device 1 from the memory controller 2. The command CMD includes, for example, a command for causing the sequencer 13 to execute a read operation, a write operation, an erase operation, and the like.

The address register 12 holds address information ADD received by the semiconductor memory device 1 from the memory controller 2. The address information ADD includes, for example, a page address PA, a block address BA, and a column address CA. For example, the page address PA, the block address BA, and the column address CA are used to select a word line, a block BLK, and a bit line, respectively.

The sequencer 13 controls the entire operation of the semiconductor memory device 1. The sequencer 13 executes the read operation, the write operation, and the erase operation based on a command CMD stored in the command register 11.

The driver module 14 generates voltages to be used in the read operation, the write operation, the erase operation, and the like. Then, the driver module 14 applies the generated voltage to the signal line corresponding to the selected word line based on, for example, the page address PA held in the address register 12.

The row decoder module 15 selects one block BLK in the corresponding memory cell array 10 based on the block address BA held in the address register 12. Then, the row decoder module 15 transfers, for example, the voltage applied to the signal line corresponding to the selected word line to the selected word line in the selected block BLK.

The sense amplifier module 16 transfers data DAT between the memory controller 2 and the memory cell array 10. The data DAT includes write data and read data. More specifically, the sense amplifier module 16 transfers the write data DAT received from the memory controller 2 to the memory cell array 10 in the write operation. In addition, the sense amplifier module 16 executes determination of data stored in the memory cell on the basis of the voltage of the bit line in the read operation. The sense amplifier module 16 transfers a result of the determination to the memory controller 2 as read data DAT.

### 1.1.3 Circuit Configuration of Memory Cell Array

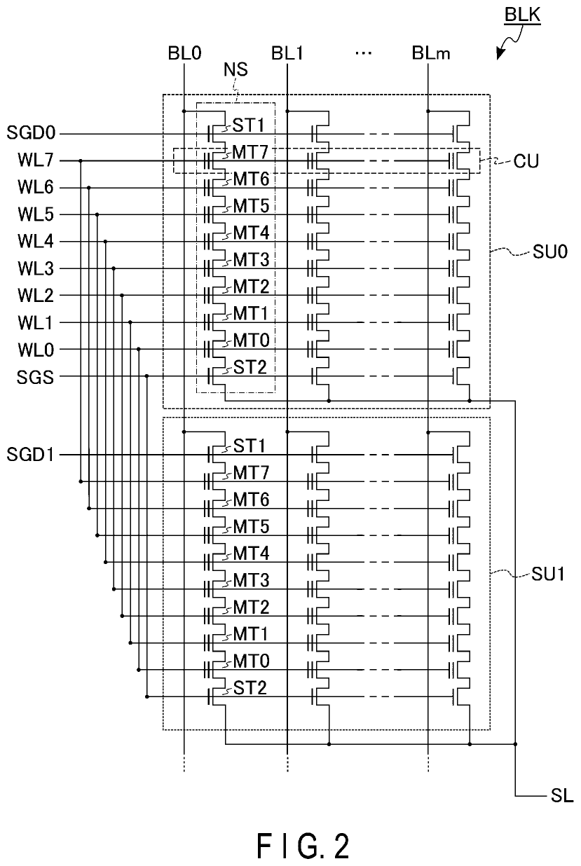

An example of a circuit configuration of the memory cell array 10 will be described with reference to FIG. 2. FIG. 2 is a circuit diagram illustrating an example of a circuit configuration of a memory cell array included in the semiconductor memory device according to the first embodiment. FIG. 2 illustrates one block BLK among the plurality of blocks BLK included in the memory cell array 10.

In the first embodiment, each block BLK includes, for example, string units SU0 and SU1. Hereinafter, when the string units SU0 and SU1 are not distinguished, each of the string units SU0 and SU1 is simply referred to as a string unit SU.

Each string unit SU includes a plurality of NAND strings NS associated with bit lines BL0 to BLm (m is an integer of 1 or more). Each NAND string NS includes, for example, memory cell transistors MT0 to MT7 and select transistors ST1 and ST2. Each of the memory cell transistors MT0 to MT7 includes a control gate and a charge storage film. Each of the memory cell transistors MT0 to MT7 holds data in a nonvolatile manner. The select transistors ST1 and ST2 are used to select the string units SU during various operations. In the following description, when the bit lines BL0 to BLm are not distinguished, each of the bit lines BL0 to BLm is simply referred to as a bit line BL. When the memory cell transistors MT0 to MT7 are not distinguished, each of the memory cell transistors MT0 to MT7 is simply referred to as a memory cell transistor MT.

In each NAND string NS, the memory cell transistors MT0 to MT7 are coupled in series. A first end of the select transistor ST1 is coupled to the bit line BL associated with the select transistor ST1. A second end of the select transistor ST1 is coupled to one end of the memory cell transistors MT0 to MT7 coupled in series. A first end of the select transistor ST2 is coupled to the other end of the memory cell transistors MT0 to MT7 coupled in series. A second end of the select transistor ST2 is coupled to a source line SL.

In the same block BLK, control gates of the memory cell transistors MT0 to MT7 are coupled to word lines WL0 to WL7, respectively. Gates of the select transistors ST1 in the string units SU0 and SU1 are coupled to select gate lines SGD0 and SGD1, respectively. On the other hand, gates of the plurality of select transistors ST2 are commonly coupled to a select gate line SGS. However, the semiconductor memory device 1 according to the embodiment is not limited thereto, and the gates of the plurality of select transistors ST2 may be coupled to a plurality of select gate lines SGS different for each string unit SU. In the following description, when the word lines WL0 to WL7 are not distinguished, each of the word lines WL0 to WL7 is simply referred to as a word line WL. When the select gate lines SGD0 and SGD1 are not distinguished, each of the select gate lines SGD0 and SGD1 is simply referred to as a select gate line SGD.

Different column addresses are allocated to the bit lines BL0 to BLm. Each bit line BL is shared by the NAND string NS to which the same column address is allocated among the plurality of blocks BLK. The word lines WL0 to WL7 are provided for each block BLK. The source line SL is shared among the plurality of blocks BLK, for example.

A set of the plurality of memory cell transistors MT coupled to the common word line WL in one string unit SU is referred to as, for example, a cell unit CU. A storage capacity of the cell unit CU including the plurality of memory cell transistors MT each storing 1-bit data is defined as, for example, “1-page data”. The cell unit CU may have a storage capacity of two page data or more according to the number of bits of data stored in the memory cell transistor MT.

Note that a circuit configuration of the memory cell array 10 is not limited to the configuration described above. For example, the number of string units SU included in each block BLK may be any number. The number of the memory cell transistors MT and the number of the select transistors ST1 and ST2 included in each NAND string NS may be any number.

### 1.1.4 Structure of Memory Cell Array

Next, a structure of the memory cell array 10 will be described. In the drawings referred to below, an X direction corresponds to an extending direction of the word line WL. A Y direction corresponds to an extending direction of the bit line BL. A Z direction corresponds to a vertical direction with respect to a surface of the semiconductor substrate used for forming the semiconductor memory device 1. In the plan view, hatching is appropriately added for easy viewing of the drawing. Hatching added to the plan view is not necessarily related to a material or a characteristic of the component to which the hatching is added. In the cross-sectional view, illustration of the configuration is appropriately omitted in order to make the view easy to see. The configurations illustrated in the drawings are appropriately simplified and illustrated.

### 1.1.4.1 Planar Structure

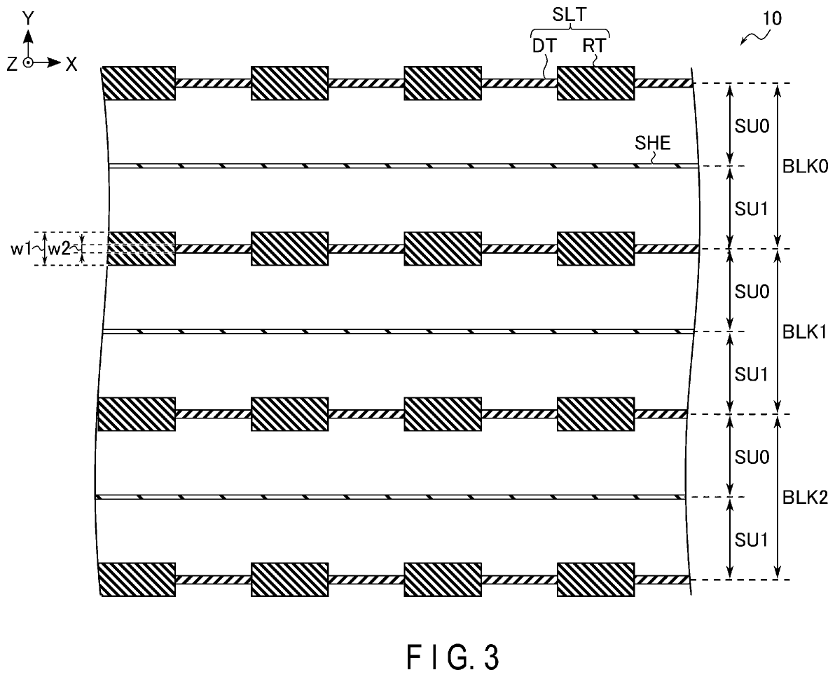

A planar structure of the memory cell array 10 will be described with reference to FIG. 3. FIG. 3 is a plan view illustrating an example of a planar layout of a memory cell array included in the semiconductor memory device according to the first embodiment. In FIG. 3, regions corresponding to three blocks BLK0, BLK1, and BLK2 are illustrated.

The memory cell array 10 includes a laminated wiring structure and a plurality of members SLT and SHE.

The laminated wiring structure is a structure laminated along the Z direction according to the select gate lines SGD and SGS and the word lines WL0 to WL7. The laminated wiring structure includes the select gate lines SGD and SGS and the word lines WL0 to WL7. In the following description, the select gate lines SGD and SGS and the word line WL are also collectively referred to as laminated wiring.

The memory cell array 10 includes a plurality of NAND strings NS (not illustrated in FIG. 3). As a result, the memory cell array 10 stores data.

Each member SLT extends in the X direction. The plurality of members SLT are arranged in the Y direction. Each member SLT divides the adjacent laminated wires through the member SLT. Each of the regions divided by the plurality of members SLT corresponds to one block BLK.

Each member SLT includes a division portion DT and a plurality of bridge portions RT. The division portion DT has, for example, a structure in which an insulator or a plate-like contact is embedded. The bridge portion RT is made of an insulating material. The insulating material includes, for example, silicon oxide. The bridge portion RT is provided on an upper end side in the Z direction of each member SLT. The plurality of bridge portions RT is arranged apart from each other along the X direction in each member SLT. When viewed from above, a width w1 of the bridge portion RT is wider than a width w2 of the division portion DT in the Y direction.

Each member SHE extends in the X direction. In the first embodiment, a case where one member SHE is provided between adjacent members SLT will be described. Each member SHE traverses the laminated wiring structure in the X direction across the memory area. Each member SHE has, for example, a structure in which an insulator is embedded. Each member SHE divides the adjacent select gate lines SGD through the member SHE, for example. Each of the regions partitioned by the plurality of members SLT and SHE corresponds to one string unit SU.

In the memory cell array 10, for example, the planar layout illustrated in FIG. 3 is repeatedly arranged in the Y direction.

The planar layout of the memory cell array 10 is not limited to the layout described above. For example, the number of members SHE arranged between the adjacent members SLT can be designed to be an arbitrary number according to the number of string units SU. Further, in the plurality of members SLT, the plurality of bridge portions RT provided in the respective members SLT may be arranged in a staggered manner, for example.

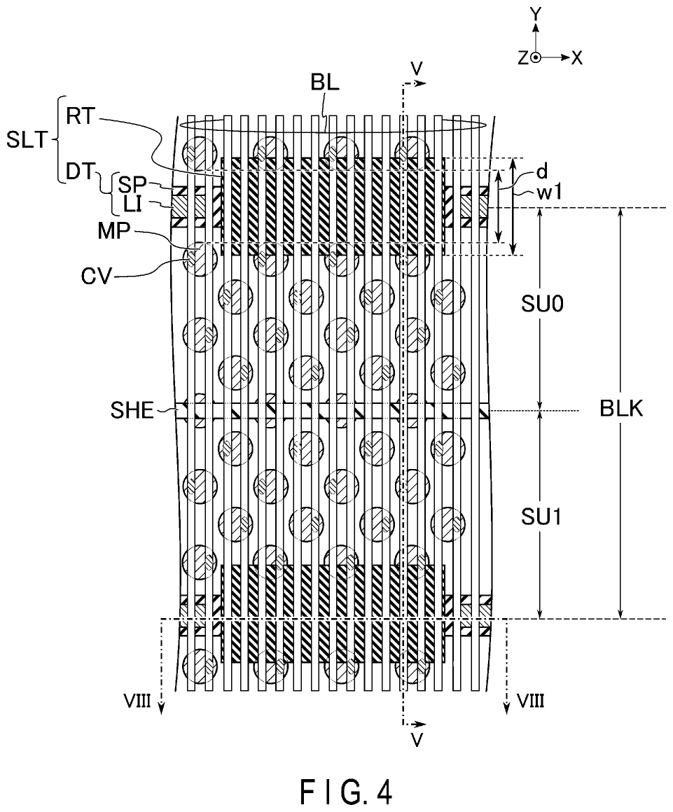

The planar structure of the memory cell array 10 will be further described with reference to FIG. 4. FIG. 4 is a plan view illustrating an example of the planar layout of the memory cell array included in the semiconductor memory device according to the first embodiment. In FIG. 4, in the structure illustrated in FIG. 3, a portion of one block BLK is mainly illustrated in an enlarged manner.

In the following description, in the string units SU0 and SU1, the string unit SU0 side is referred to as one end side in the Y direction, and the string unit SU1 side is referred to as the other end side in the Y direction.

The memory cell array 10 further includes a plurality of memory pillars MP, a plurality of contacts CV, and a plurality of bit lines BL. The division portion DT includes a contact LI and a spacer SP.

Each memory pillar MP functions as, for example, one NAND string NS. The block BLK includes a column of memory pillars in which the plurality of memory pillars MP is arranged in the X direction. In each block BLK, for example, nine columns of memory pillars MP are arranged in the Y direction. The plurality of memory pillars MP is arranged in a staggered manner, for example. In each block BLK, for example, the member SHE overlaps the memory pillar MP of a fifth column counted from one end side in the Y direction.

Each bit line BL extends in the Y direction. The plurality of bit lines BL is arranged in the X direction. Each bit line BL is arranged so as to overlap at least one memory pillar MP for each string unit SU. In the example of FIG. 4, each bit line BL is arranged so as to overlap two memory pillars MP for each string unit SU. One bit line BL among the plurality of bit lines BL overlapping the memory pillar MP is electrically coupled to the memory pillar MP through a contact CV.

Note that the number and arrangement of the memory pillars MP in each block BLK are not limited to the configuration described with reference to FIG. 4, and can be appropriately changed. The number of bit lines BL overlapping each memory pillar MP can be designed to an arbitrary number.

The width w1 of the bridge portion RT is equal to or larger than a distance d between the two memory pillars MP adjacent to the member SLT on one end side and the other end side in the Y direction. The distance d is, for example, a distance between the memory pillar MP of the first column counted from one end side in the Y direction of one block BLK and the memory pillar MP of the first column counted from the other end side in the Y direction of the block BLK adjacent to the block BLK on one end side in the Y direction. As a result, the bridge portion RT has at least a portion overlapping the memory pillar MP adjacent to the member SLT in the Y direction when viewed from above. The distance d is wider than the width w2 of the division portion DT. In the following description, two memory pillars MP adjacent to the member SLT on one end side and the other end side in the Y direction are also simply referred to as two memory pillars MP sandwiching the member SLT.

More specifically, in the Y direction, the bridge portion RT included in the member SLT on one end side of each block BLK overlaps the three memory pillars MP included in the column of the memory pillar MP of the first column counted from one end side among the columns of the nine columns of memory pillars MP when viewed from above. In the Y direction, the bridge portion RT included in the member SLT on the other end side of each block BLK overlaps the three memory pillars MP included in the column of the memory pillar MP of the first column from the other end side among the columns of the nine columns of memory pillars MP when viewed from above. In each block BLK, the number of memory pillars MP overlapping each bridge portion RT when viewed from above is not limited to three. The number of memory pillars MP overlapping the bridge portion RT when viewed from above may be 0 to 2 or 4 or more.

In the division portion DT, the contact LI is, for example, a conductor having a portion extending in the X direction. The spacer SP is, for example, an insulator provided on a side surface of the contact LI and between the bridge portion RT and the contact LI. The contact LI and the laminated wiring adjacent to the contact LI in the Y direction are separated by the spacer SP. As a result, the contact LI and the laminated wiring adjacent to the contact LI in the Y direction are electrically insulated from each other. In addition, in a lower region (not illustrated), the spacer SP may be provided so as to partially cover a lower surface of the contact LI. Note that the contact LI may be an insulator. In this case, the spacer SP and the contact LI can be integrally formed.

### 1.1.4.2 Cross-Sectional Structure

Next, a cross-sectional structure of the memory cell array 10 will be described.

### 1.1.4.2.1 Overall Structure

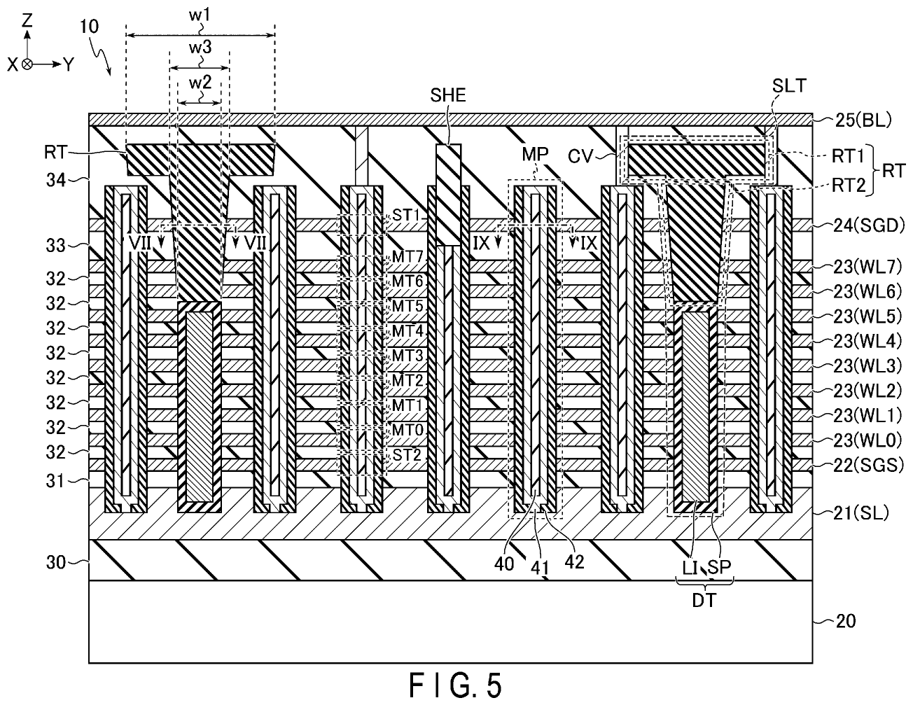

The overall structure of the memory cell array 10 in a YZ plane will be described with reference to FIG. 5. FIG. 5 is a cross-sectional view taken along line V-V of FIG. 4, illustrating an example of a cross-sectional structure in a YZ plane of the memory cell array included in the semiconductor memory device according to the first embodiment.

The memory cell array 10 further includes a semiconductor substrate 20, conductor layers 21 to 25, and insulator layers 30 to 34.

More specifically, a laminated wiring structure is provided on the semiconductor substrate 20 with the insulator layer 30 interposed therebetween. The insulator layer 30 includes circuits (not illustrated) such as the row decoder module 15 and the sense amplifier module 16. In the present specification, a direction in which the laminated wiring structure of the memory cell array 10 is provided with respect to the semiconductor substrate 20 is defined as an upward direction.

The conductor layer 21 is provided on the insulator layer 30. The conductor layer 21 is formed in, for example, a plate shape extending along the XY plane. The conductor layer 21 is used as the source line SL. The conductor layer 21 includes, for example, phosphorus-doped silicon.

The insulator layer 31 is provided on the conductor layer 21. The conductor layer 22 is provided on the insulator layer 31. The conductor layer 22 is formed in, for example, a plate shape extending along the XY plane. The conductor layer 22 is used as the select gate line SGS. The conductor layer 22 contains, for example, tungsten or molybdenum.

A plurality of the insulator layers 32 and a plurality of the conductor layers 23 are laminated on the conductor layer 22. The plurality of insulator layers 32 and the plurality of conductor layers 23 are laminated in the order of the insulator layer 32, the conductor layer 23, the insulator layers 32, . . . the conductor layer 23, the insulator layer 32, and the conductor layer 23 upward. The conductor layer 23 is formed in, for example, a plate shape extending along the XY plane. The plurality of laminated conductor layers 23 is used as the word lines WL0 to WL7 in order from the semiconductor substrate 20 side. The conductor layer 23 contains, for example, tungsten or molybdenum.

The insulator layer 33 is provided on the uppermost conductor layer 23. The conductor layer 24 is provided on the insulator layer 33. The conductor layer 24 is formed in, for example, a plate shape extending along the XY plane. The conductor layer 24 is used as the select gate line SGD. The conductor layer 24 contains, for example, tungsten or molybdenum.

The insulator layer 34 is provided on the conductor layer 24. A plurality of the conductor layers 25 is provided on the insulator layer 34. Each conductor layer 25 is formed in, for example, a line shape extending in the Y direction. Each conductor layer 25 is used as the bit line BL. The conductor layer 25 contains, for example, copper. The insulator layers 30 to 34 includes, for example, silicon oxide.

Each of the memory pillars MP is provided to extend along the Z direction, and penetrates the insulator layers 31 to 33 and the conductor layers 22 to 24. A bottom portion of the memory pillar MP is in contact with the conductor layer 21. A portion where the memory pillar MP intersects the conductor layer 22 functions as the select transistor ST2. A portion where the memory pillar MP intersects one conductor layer 23 functions as one memory cell transistor MT. A portion where the memory pillar MP intersects the conductor layer 24 functions as the select transistor ST1.

Each of the memory pillars MP includes, for example, a core member 40, a semiconductor layer 41, and a laminated film 42. The core member 40 is provided to extend along the Z direction. An upper end of the core member 40 is positioned, for example, above the conductor layer 24. A lower end of the core member 40 is located, for example, below the conductor layer 22. The semiconductor layer 41 covers a periphery of the core member 40. In a lower portion of the memory pillar MP, a part of the semiconductor layer 41 is in contact with the conductor layer 21. The laminated film 42 covers a side surface and a bottom surface of the semiconductor layer 41 except for a portion where the semiconductor layer 41 and the conductor layer 21 are in contact with each other. The core member 40 includes an insulator such as silicon oxide. The semiconductor layer 41 contains, for example, silicon.

A pillar-shaped contact CV is provided on an upper surface of the semiconductor layer 41 in the memory pillar MP. In the illustrated region, three contacts CV respectively corresponding to the three memory pillars MP among the seven memory pillars MP are displayed. In the memory region, the contact CV is coupled to the memory pillar MP which does not overlap the member SHE and to which the contact CV is not coupled in a region not illustrated.

An upper surface of the contact CV is electrically coupled to one conductor layer 25. The contact CV is provided such that one contact CV is coupled to one conductor layer 25 in each of the spaces divided by the members SLT and SHE. That is, one memory pillar MP included in each string unit SU is electrically coupled to each of the conductor layers 25.

The member SLT has, for example, a portion provided along an XZ plane, and divides the conductor layer 22 to 24 in the Y direction. Details of the structure of the member SLT will be described later.

The member SHE has, for example, a portion provided along the XZ plane, and divides the conductor layer 24 in the Y direction. An upper surface of the member SHE is positioned, for example, at the same height as an upper surface of the member SLT, but is not limited to the configuration. The upper surface of the member SHE may be positioned between an upper surface of the conductor layer 24 and a lower surface of the conductor layer 25, and the upper surface of the member SHE and the upper surface of the member SLT may be aligned or may not be aligned. A lower surface of the member SHE is located between the uppermost conductor layer 23 and the conductor layer 24. The member SHE includes, for example, an insulator such as silicon oxide.

### 1.1.4.2.2 Cross-Sectional Structure of Member SLT

Next, a cross-sectional structure of the member SLT will be specifically described.

### (YZ Plane)

First, the cross-sectional structure of the member SLT in the YZ plane will be subsequently described with reference to FIG. 5.

FIG. 5 illustrates an example of a cross section in which each member SLT includes the bridge portion RT on an upper layer side, and is adjacent to a memory pillar MP on one end side in the Y direction and a memory pillar MP on the other end side in the Y direction.

Each of the bridge portions RT includes, for example, a first bridge portion RT1 and a second bridge portion RT2. The first bridge portion RT1 is a portion included above the second bridge portion RT2.

A first bridge portion RT1 is, for example, a layer above an upper surface of the memory pillar MP and included in a region below a lower surface of the conductor layer 25. As a result, the first bridge portion RT1 is separated from the memory pillar MP. As illustrated on one end side along the Y direction in FIG. 5, the first bridge portion RT1 can be in contact with, for example, contacts CV coupled to two memory pillars MP sandwiching the member SLT. Further, as illustrated on the other end side along the Y direction in FIG. 5, in the region not including the contacts CV coupled to the two memory pillars MP sandwiching the member SLT, a width of an upper surface of the first bridge portion RT1 along the Y direction is equal to a width w1 of the bridge portion RT when viewed from above.

In the first embodiment, an example in which the bridge portion RT is in contact with the contacts CV coupled to the two memory pillars MP sandwiching the member SLT in the first bridge portion RT1 has been described, but is not limited to the configuration. The bridge portion RT may not be in contact with the contacts CV coupled to the two memory pillars MP sandwiching the member SLT. In this case, the width of the first bridge portion RT1 in the Y direction is equal to the width w1 regardless of the position in the X direction, for example.

The second bridge portion RT2 includes a lower surface of the bridge portion RT. The lower surface of the bridge portion RT is positioned, for example, below the upper surface of the conductor layer 24 corresponding to the select gate line SGD. FIG. 5 shows an example in which the lower surface of the bridge portion RT is located between the upper surface of the conductor layer 23 corresponding to the word line WL5 and the lower surface of the conductor layer 23 corresponding to the word line WL6.

In the Y direction, a width of a lower surface of the second bridge portion RT2 is, for example, equal to the width w2 of the division portion DT. On the other hand, the second bridge portion RT2 has a width w3 in the vicinity of a boundary between the first bridge portion RT1 and the second bridge portion RT2. The width w3 is narrower than the width w1 and wider than the width w2. With the above configuration, the second bridge portion RT2 has a tapered shape in which the width of the second bridge portion RT2 increases from the lower side to the upper side in the Y direction. In the first embodiment, the width w2 and the width w3 are narrower than the distance d between the two memory pillars MP sandwiching the member SLT. As a result, the second bridge portion RT2 is separated from the two memory pillars MP sandwiching the member SLT.

In FIG. 5, a case where the width of the lower surface of the second bridge portion RT2 and the width w2 of the division portion DT are substantially equal in the Y direction is illustrated, but is not limited to the configuration. The width of the lower surface of the second bridge portion RT2 may be equal to or larger than the width w2 of the division portion DT.

With the above configuration, the bridge portion RT is provided apart from the memory pillar MP. The bridge portion RT has, for example, a convex shape in which the second bridge portion RT2 protrudes downward from the first bridge portion RT1. As a result, the bridge portion RT has, for example, a stepped structure on each of one end side and the other end side in the Y direction.

In the region where the member SLT includes the bridge portion RT, an upper surface of the division portion DT is provided depending on a height of a lower surface of the bridge portion RT. In the example illustrated in FIG. 5, the upper surface of the division portion DT is located between an upper surface of the conductor layer 23 corresponding to the word line WL5 and a lower surface of the conductor layer 23 corresponding to the word line WL6.

In the cross section illustrated in FIG. 5, the spacer SP is provided, for example, between the contact LI and the bridge portion RT, on a side surface of the contact LI, and between a lower surface of the contact LI and the conductor layer 21. That is, in the region where the member SLT includes the bridge portion RT, the spacer SP can be provided so as to cover an upper surface, the side surface, and the lower surface of the contact LI. Although not illustrated in FIG. 5, the contact LI is in contact with the conductor layer 21 in a region where the member SLT does not include the bridge portion RT.

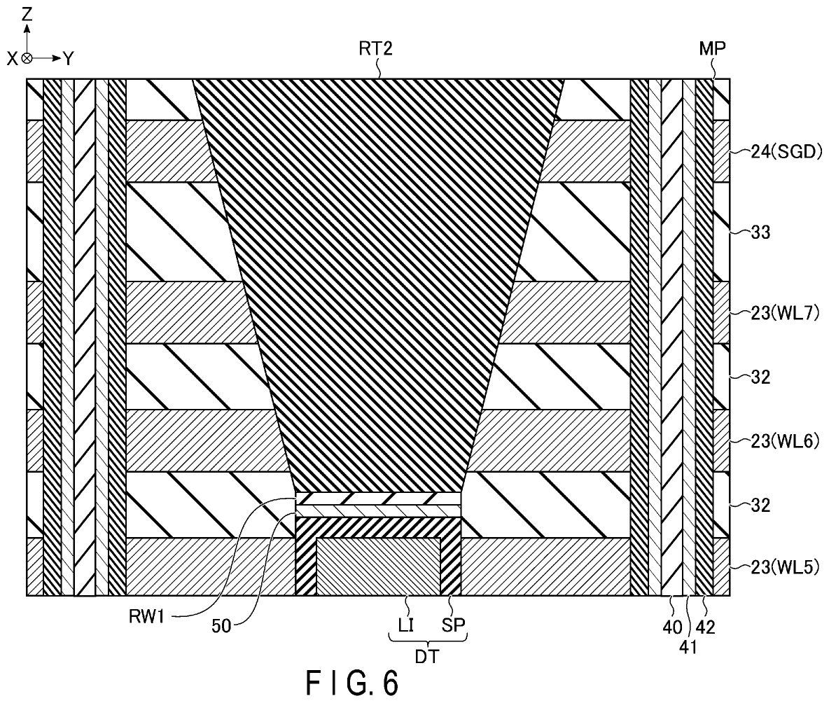

The bridge portion RT and a cross-sectional structure in the vicinity thereof in the YZ plane according to the first embodiment will be further described with reference to FIG. 6. FIG. 6 is a cross-sectional view illustrating an example of a cross-sectional structure of the memory cell array included in the semiconductor memory device in the YZ plane according to the first embodiment. FIG. 6 shows an enlarged view of the vicinity of the second bridge portion RT2.

As described above, the second bridge portion RT2 has a tapered shape in which the width of the second bridge portion RT2 increases from the lower side to the upper side in the Y direction. As a result, a length of the laminated wiring of the upper layer in the Y direction is shorter than a length of the laminated wiring of the lower layer in the Y direction between a side surface of the bridge portion RT and a side surface of the memory pillar MP adjacent to the member SLT. In the example illustrated in FIG. 6, a length of the conductor layer 23 corresponding to the word line WL6, a length of the conductor layer 23 corresponding to the word line WL7, and a length of the conductor layer 24 corresponding to the select gate line SGD are shortened in this order between the bridge portion RT and the memory pillar MP adjacent to the bridge portion RT.

In the memory cell array 10 according to the first embodiment, a metal element-containing layer containing a metal oxide or the like may be included between the bridge portion RT and the spacer SP of the division portion DT.

More specifically, the insulator RW1 may be provided between the bridge portion RT and the spacer SP. The insulator RW1 is in contact with a lower surface of the bridge portion RT. The insulator RW1 is a high dielectric film made of an insulating material. The insulator RW1 contains, for example, a metal oxide such as aluminum oxide. Furthermore, a conductor 50 may be formed on a lower surface side of the insulator RW1 between the insulator RW1 and the spacer SP. The conductor 50 may contain a conductive material such as tungsten, molybdenum, and titanium nitride.

With the configuration including the insulator RW1 and the conductor 50 as described above, for example, even when the contact LI is an insulator, the bridge portion RT and the division portion DT can be distinguished from each other.

Although not illustrated in FIG. 6, each of the conductor layers 22 to 24 includes, for example, a liner-shaped insulator containing a metal oxide such as aluminum oxide and a conductor containing a conductive material as described later. In the insulator RW1, the metal oxide contained in the liner-shaped insulator remains without being completely removed from an inside of a slit when the conductor layers 22 to 24 are formed. In the conductor 50, the conductive material contained in the conductor layers 22 to 24 remains without being completely removed from the inside of the slit when the conductor layers 22 to 24 are formed. The insulator RW1 may be included in an arbitrary region of the side surface of the member SLT including the bridge portion RT and the division portion DT.

FIGS. 5 and 6 show a case where the thicknesses of all the insulator layers 32 are equal to each other, but is not limited to the configuration. For example, when the lower surface of the bridge portion RT is included at the same height as a predetermined insulator layer 32, the insulator layer 32 may be provided thicker than the other insulator layers 32. When the lower surface of the bridge portion RT is included at the same height as the insulator layer 33, the insulator layer 33 may be provided thicker than each insulator layer 32.

### (XY Plane)

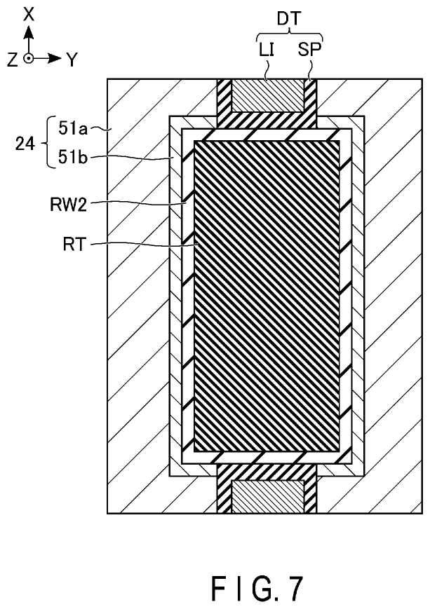

Next, a cross-sectional structure of the bridge portion RT in the XY plane according to the first embodiment will be further described with reference to FIG. 7. FIG. 7 is a cross-sectional view taken along line VII-VII of FIG. 5, illustrating an example of a cross-sectional structure in the XY plane of the memory cell array included in the semiconductor memory device according to the first embodiment. FIG. 7 illustrates a cross-sectional view of the vicinity of the bridge portion RT in the XY plane including the conductor layer 24 corresponding to the select gate line SGD.

Hereinafter, a case where each of the conductor layers 22 to 24 includes conductors 51a and 51b including a conductive material will be described. In addition, a case where the insulator RW2 is provided as a liner-like insulator between the conductor 51b and the bridge portion RT will be described.

In the cross section illustrated in FIG. 7, the bridge portion RT has, for example, a rectangular shape.

The side surface of the bridge portion RT in the Y direction is covered with the insulator RW2. In addition, the insulator RW2 may have a portion in contact with the division portion DT along the side surface of the bridge portion RT in the X direction. The insulator RW2 is a high dielectric film made of an insulating material. The insulator RW2 contains, for example, a metal oxide such as aluminum oxide. The insulator RW2 functions as a block insulating film of the memory cell transistor MT together with the block insulating film in the laminated film 42 of the memory pillar MP.

A structure of the conductor layer 24 included in the same layer as the bridge portion RT will be described.

The conductor 51a mainly forms, for example, a plate-like structure of the conductor layer 24. The conductor 51a is made of a metal material such as tungsten or molybdenum.

The conductor 51b covers a side surface of the insulator RW2 in the Y direction. The conductor 51b is in contact with the conductor 51a. The conductor 51b is made of a conductive material such as titanium nitride. The conductor 51b functions as a barrier layer of the conductor 51a.

### (XZ Plane)

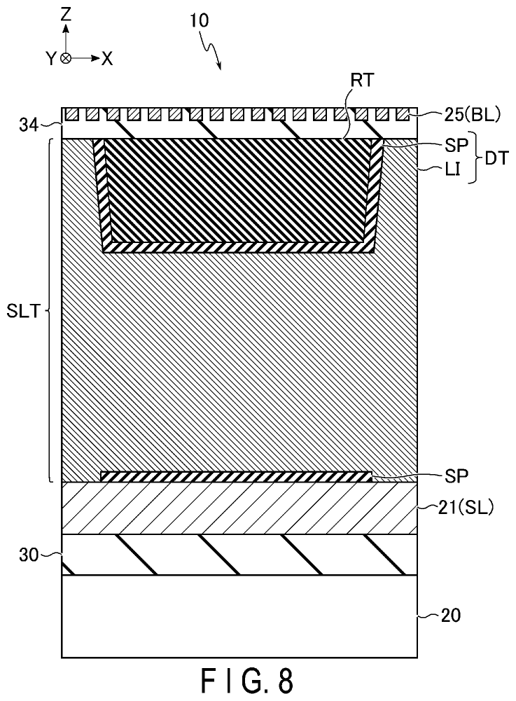

Next, a cross-sectional structure of the bridge portion RT in the XZ plane according to the first embodiment will be further described with reference to FIG. 8. FIG. 8 is a cross-sectional view taken along line VIII-VIII of FIG. 4, illustrating an example of a cross-sectional structure in the XZ plane of the memory cell array included in the semiconductor memory device according to the first embodiment. In FIG. 8, illustration of the insulators RW1 and RW2 and the conductor 50 is omitted.

The bridge portion RT has, for example, a tapered shape in which a width of the bridge portion RT along the X direction increases upward in the XZ plane.

The division portion DT is provided, for example, in a range of the same height as an upper surface of the bridge portion RT from a lower surface of the member SLT. The contact LI is provided in a region below the bridge portion RT and a region sandwiching the bridge portion RT in the X direction. The contact LI is mainly included in the division portion DT. The spacer SP covers the side surface and the lower surface of the bridge portion RT between the contact LI and the bridge portion RT. A side surface and a lower surface of the spacer SP covering the bridge portion RT are covered with the contact LI. Furthermore, the spacer SP is provided on an upper surface of the conductor layer 21, for example, at a position overlapping the bridge portion RT when viewed from above. In addition, the side surface and an upper surface of the spacer SP provided on the upper surface of the conductor layer 21 are covered with the contact LI. The contact LI is in contact with the conductor layer 21 at a position sandwiching the bridge portion RT in the X direction when viewed from above.

### 1.1.4.2.3 Structure of Memory Pillar

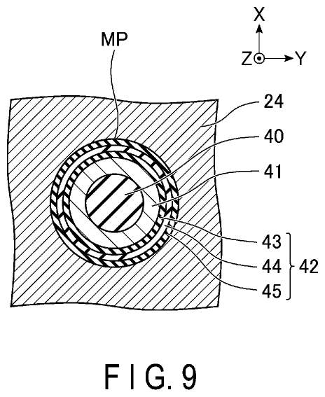

A structure of the memory pillar MP in the semiconductor memory device 1 according to the first embodiment will be described with reference to FIG. 9. FIG. 9 is a cross-sectional view taken along line IX-IX of FIG. 5, illustrating an example of a cross-sectional structure of the memory pillar of the memory cell array included in the semiconductor memory device according to the first embodiment.

The laminated film 42 includes, for example, a tunnel insulating film 43, an insulating film 44, and a block insulating film 45.

In the cross section including the conductor layer 24, the core member 40 is provided at a central portion of the memory pillar MP. The core member 40 has, for example, a circular shape in the XY plane. The semiconductor layer 41 surrounds a side surface of the core member 40. The tunnel insulating film 43 surrounds a side surface of the semiconductor layer 41. The insulating film 44 surrounds a side surface of the tunnel insulating film 43. The block insulating film 45 surrounds a side surface of the insulating film 44. The conductor layer 24 surrounds a side surface of the block insulating film 45. Each of the tunnel insulating film 43 and the block insulating film 45 contains, for example, silicon oxide. The insulating film 44 contains, for example, silicon nitride.

With the above configuration, the memory pillar MP has, for example, a circular shape in the XY plane.

In the memory pillar MP described above, the semiconductor layer 41 functions as current paths of the memory cell transistors MT0 to MT7 and the select transistors ST1 and ST2. In addition, the insulating film 44 is used as a charge storage layer of the memory cell transistor MT. The semiconductor memory device 1 causes a current to flow in the memory pillar MP between the bit line BL and the source line SL by turning on the memory cell transistors MT0 to MT7 and the select transistors ST1 and ST2.

### 1.2 Method for Manufacturing Semiconductor Memory Device

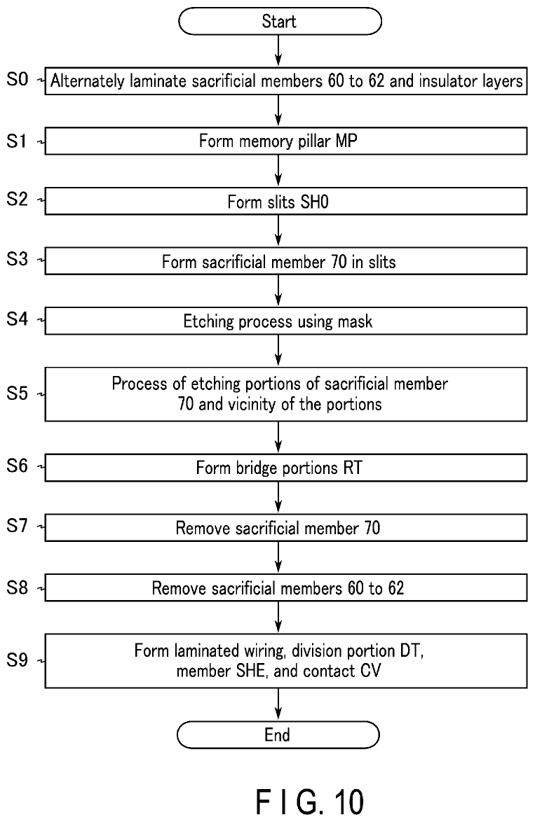

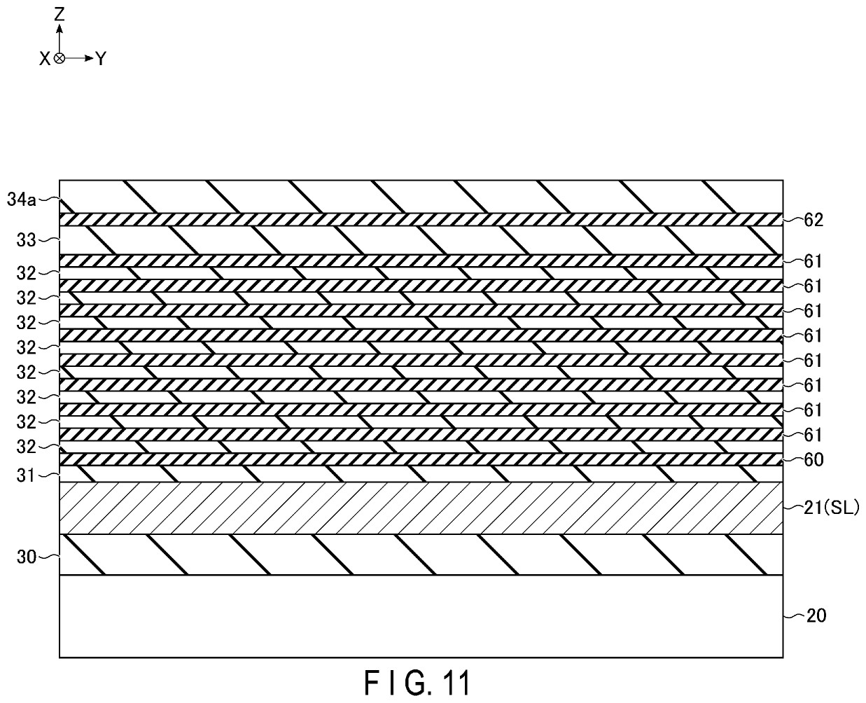

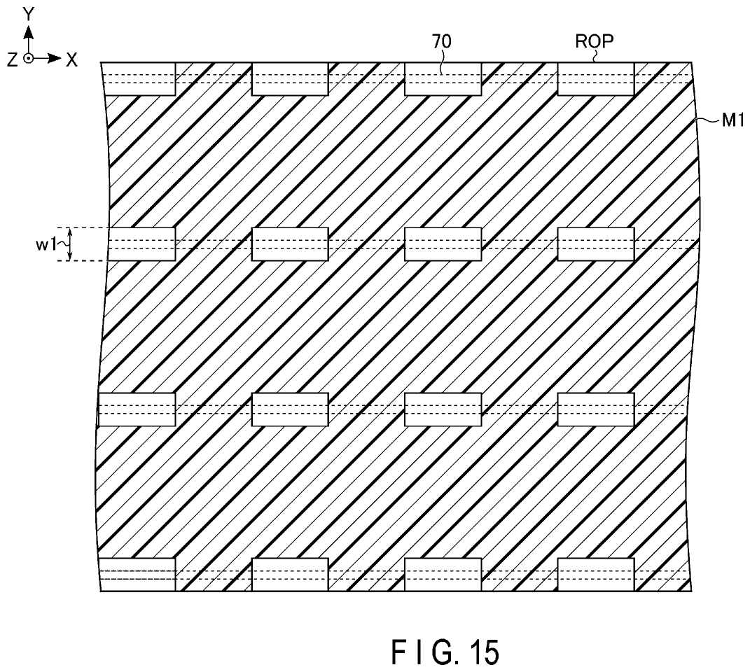

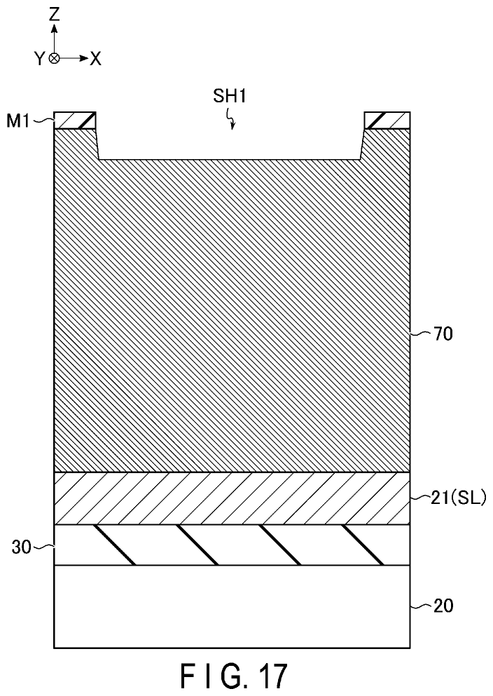

A method for manufacturing the semiconductor memory device 1 will be described with reference to FIGS. 10 to 26. FIG. 10 is a flowchart illustrating an example of a method for manufacturing the semiconductor memory device according to the first embodiment. FIGS. 11 to 14 and FIGS. 16 to 26 are cross-sectional views illustrating an example of the method for manufacturing the semiconductor memory device according to the first embodiment. FIG. 15 is a plan view illustrating an example of the method for manufacturing the semiconductor memory device according to the first embodiment. The cross-sectional views illustrated in FIGS. 11 to 14, 16, 18, 20, 22, 24, and 25 correspond to the region illustrated in FIG. 5. FIGS. 17, 19, 21, 23, and 26 correspond to the region illustrated in FIG. 8. FIG. 15 corresponds to the region illustrated in FIG. 3.

As illustrated in FIG. 10, in the method for manufacturing the semiconductor memory device according to the first embodiment, processes of S0 to S9 are sequentially executed. Hereinafter, an example of a method for manufacturing the semiconductor memory device 1 according to the first embodiment will be described with reference to FIG. 10 as appropriate.

In S0 of FIG. 10, as illustrated in FIG. 11, sacrificial members and insulator layers are alternately laminated.

More specifically, the insulator layer 30 including a circuit (not illustrated) such as the row decoder module 15 and the sense amplifier module 16 is formed on the semiconductor substrate 20. On the insulator layer 30, the conductor layer 21 and the insulator layer 31 are formed in this order. One sacrificial member 60 is formed on the insulator layer 31. On the sacrificial member 60, eight sacrificial members 61 and eight insulator layers 32 are formed in the order of the insulator layer 32, the sacrificial member 61, the insulator layers 32, . . . the insulator layer 32, and the sacrificial member 61. One insulator layer 33, one sacrificial member 62, and one insulator layer 34a are laminated in this order on the uppermost sacrificial member 61. As described above, a laminated body having a structure in which the sacrificial members 60 to 62 and the insulator layers 32 to 34a are alternately laminated is formed. The sacrificial members 60 to 62 includes, for example, silicon nitride. The sacrificial member 60, the 8-layer sacrificial member 61, and the sacrificial member 62 illustrated in FIG. 11 are associated with the select gate line SGS, the word lines WL0 to WL7, and the select gate line SGD, respectively.

Next, in S1 of FIG. 10, the memory pillar MP is formed.

More specifically, a mask in which a region where the memory pillar MP is to be formed is opened is formed by photolithography or the like. Then, a memory hole is formed by anisotropic etching using the formed mask. The anisotropic etching in this step is, for example, reactive ion etching (RIE). The memory hole penetrates each of the insulator layers 31 to 34a and the sacrificial members 60 to 62. A bottom of the memory hole is located, for example, between an upper surface and a lower surface of the conductor layer 21. Then, the block insulating film 45, the insulating film 44, and the tunnel insulating film 43 are formed in this order on a side surface and a bottom surface of the memory hole. Thus, the laminated film 42 is formed. Thereafter, a part of the block insulating film 45, the insulating film 44, and the tunnel insulating film 43 at the bottom of the memory hole is removed. In the memory hole from which the removal has been performed, the semiconductor layer 41 is formed on a surface of the tunnel insulating film 43. The semiconductor layer 41 is in contact with the conductor layer 21. Further, the core member 40 is formed, and an inside of the memory hole is embedded by the core member 40. As a result, the memory pillar MP is formed.

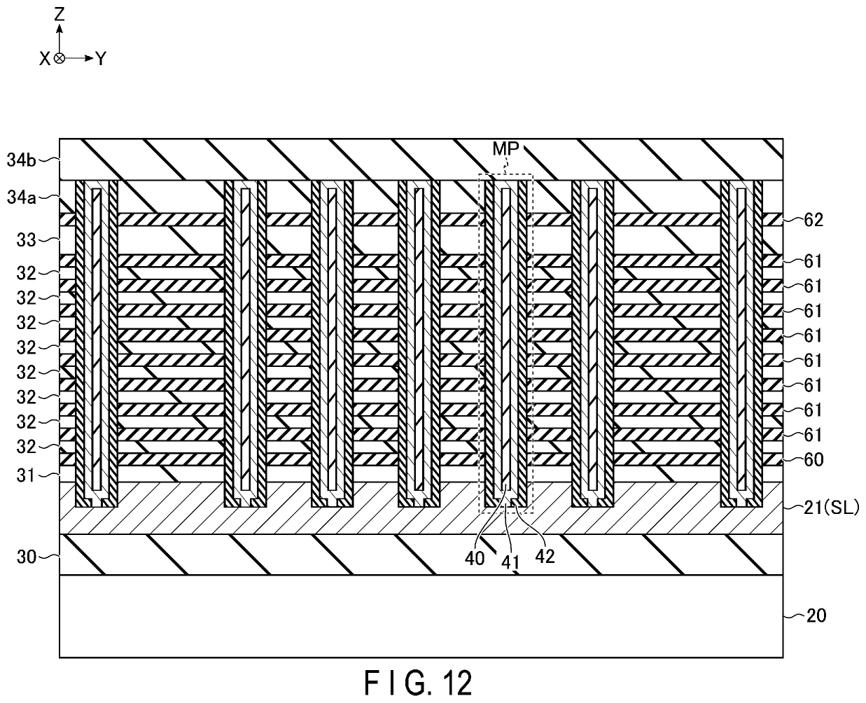

Then, as illustrated in FIG. 12, the insulator layer 34b is formed on an upper surface of the insulator layer 34a and an upper surface of the memory pillar MP.

Then, in S2 of FIG. 10, slits SH0 are formed. The slits SH0 are formed so as to include a region where the division portion DT is to be formed.

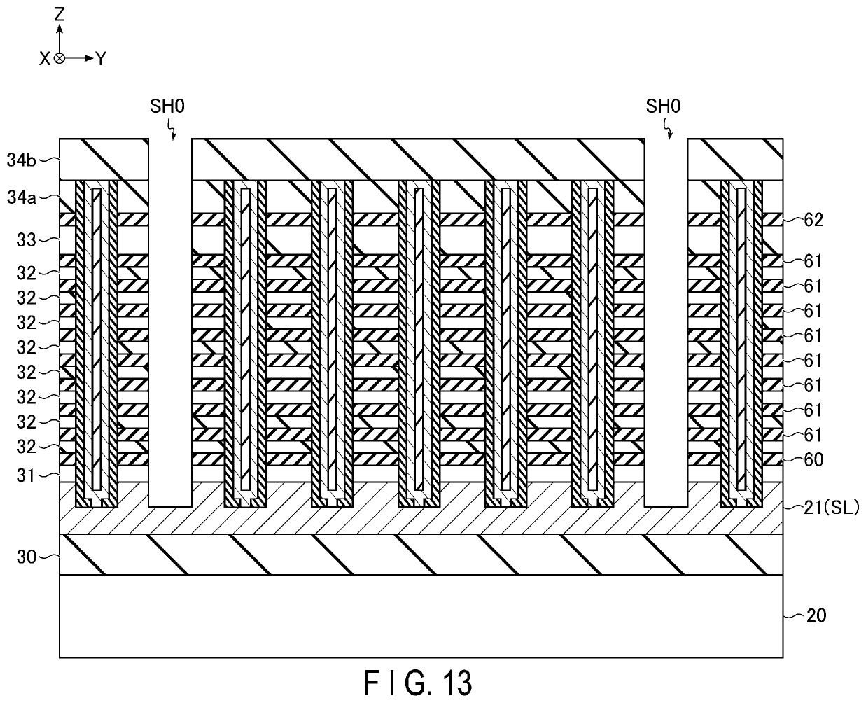

More specifically, a mask in which regions corresponding to the slits SH0 are opened is formed by photolithography or the like. Then, as illustrated in FIG. 13, the slits SH0 are formed by anisotropic etching using the mask. The slits SH0 divide each of the insulator layers 31 to 34b and the sacrificial members 60 to 62, for example.

Next, in S3 of FIG. 10, a sacrificial member 70 is formed in each slit SH0.

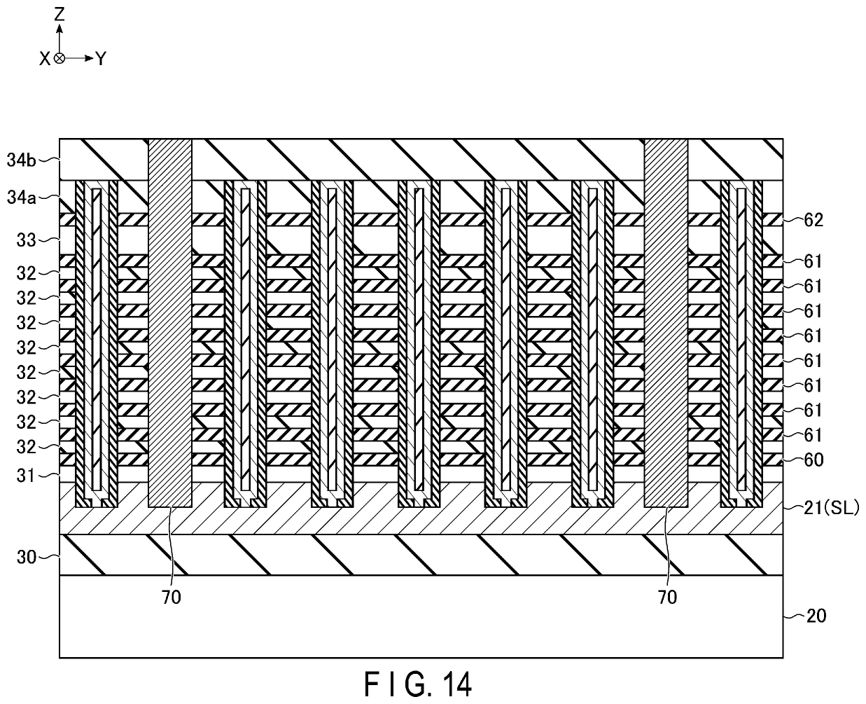

More specifically, as illustrated in FIG. 14, the sacrificial member 70 is formed so as to embed each slit SH0. The sacrificial member 70 includes, for example, amorphous silicon.

Then, in S4 of FIG. 10, the slits SH1 used to form the bridge portions RT are formed by the etching process using the mask.

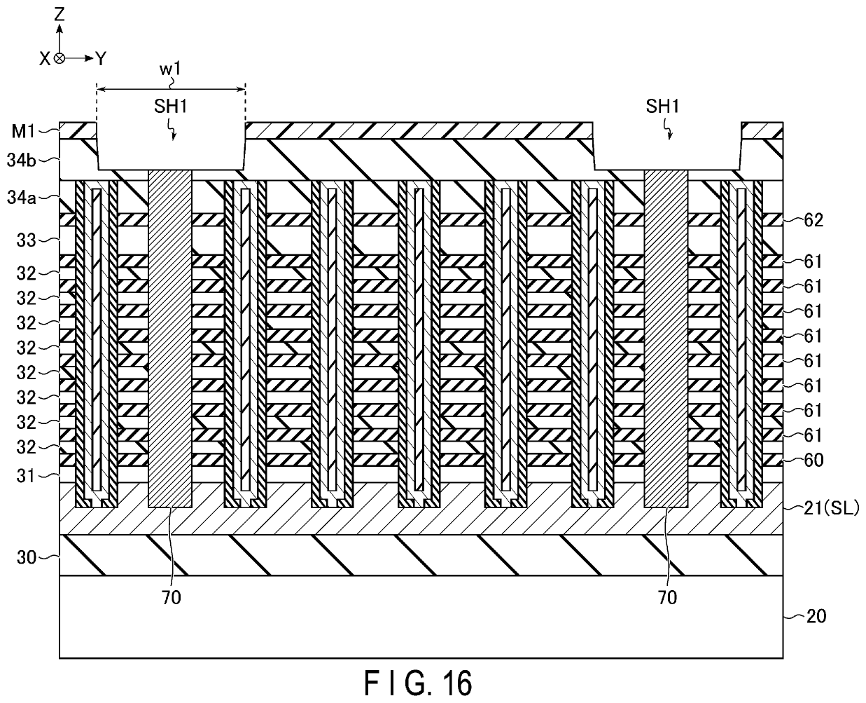

More specifically, a mask M1 having a plurality of openings ROP is formed on an upper surface of the portion of the formed insulator layer 34b and an upper surface of the portion of the sacrificial member 70. As illustrated in FIG. 15, the plurality of openings ROP are arranged above the respective sacrificial members 70 indicated by dotted lines and spaced apart from each other along the X direction. The plurality of openings ROP is associated with the plurality of bridge portions RT. In the Y direction, a width of the openings ROP is, for example, equal to the width w1 of the first bridge portion RT1. Then, as shown in FIGS. 16 and 17, for example, a region of the sacrificial member 70 and the insulator layer 34b where the first bridge portion RT1 is to be formed is removed through anisotropic etching using the formed mask M1. The slits SH1 are formed by such anisotropic etching using the mask M1. The anisotropic etching in this step is, for example, RIE.

Then, in S5 of FIG. 10, etching process of portions of the sacrificial member 70 and the vicinity of the portions is executed.

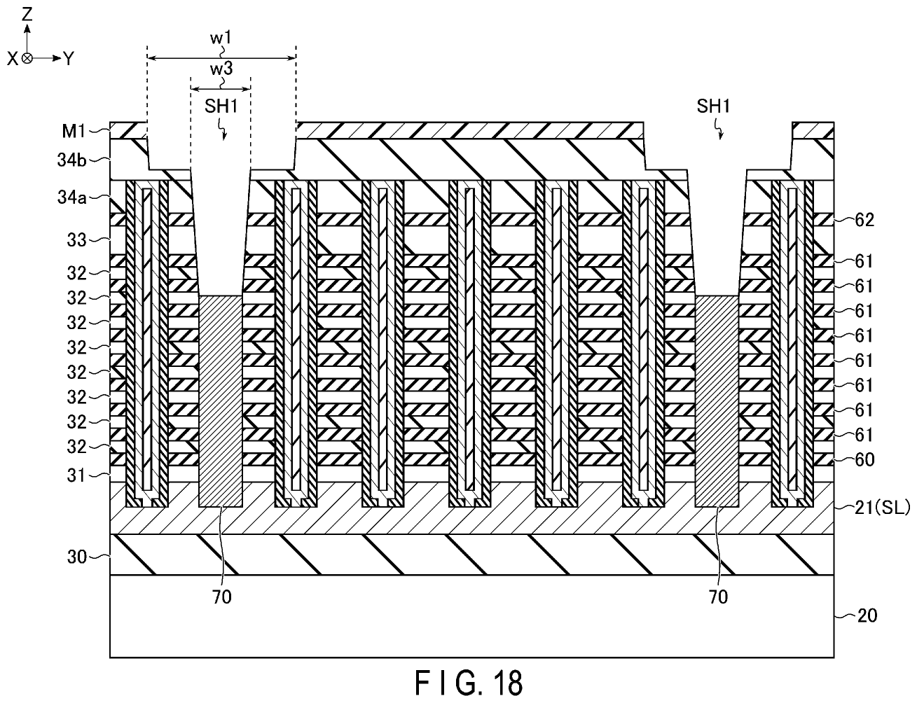

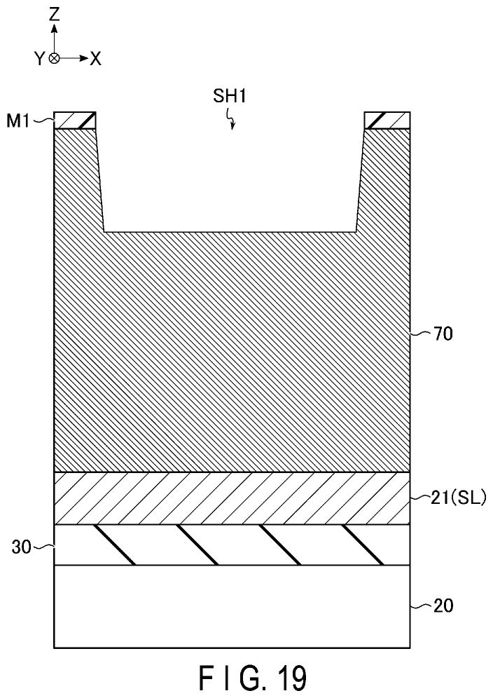

More specifically, as shown in FIGS. 18 and 19, for example, regions of the sacrificial members 61, 62, and 70 and the insulator layers 32, 33, 34a, and 34b where the second bridge portions RT2 are to be formed are removed by anisotropic etching. That is, similarly to the second bridge portion RT2, a portion of the slit SH1 having a tapered shape in which a width of the opening portion along the Y direction increases upward is formed. The anisotropic etching in this step is, for example, RIE.

Through the processes of S4 and S5 as described above, the slits SH1 are formed in the region where the bridge portion RT is to be formed.

After the process of S5 has been completed, the mask M1 is removed.

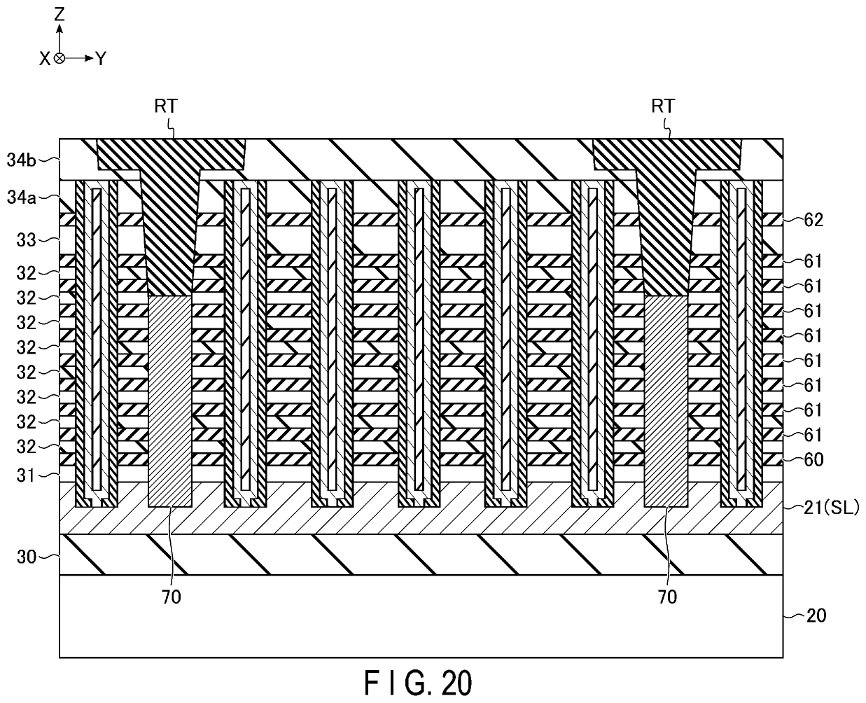

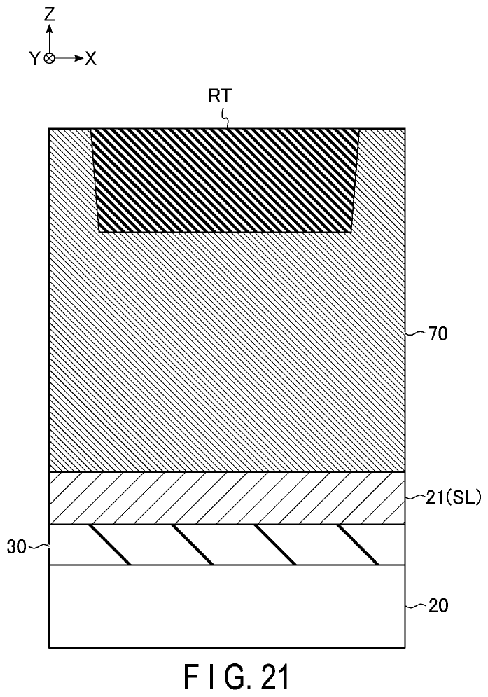

Next, in S6 of FIG. 10, as shown in FIGS. 20 and 21, the bridge portions RT are formed.

More specifically, the bridge portions RT are formed so as to embed the slits SH1 formed by the processes of S4 and S5 with the insulator. Here, the insulator formed outside the slits SH1 is removed by, for example, chemical mechanical polishing (CMP).

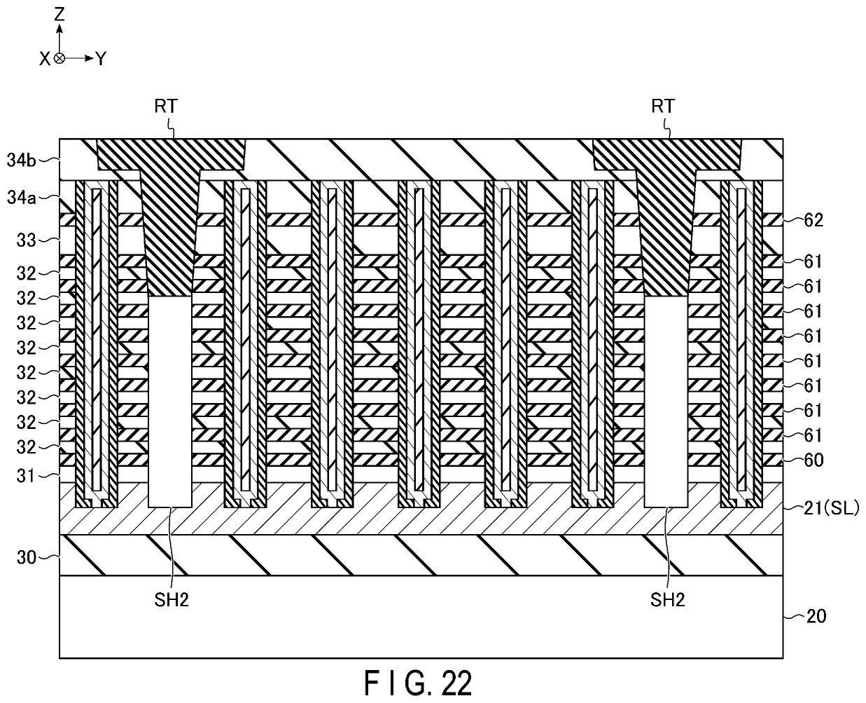

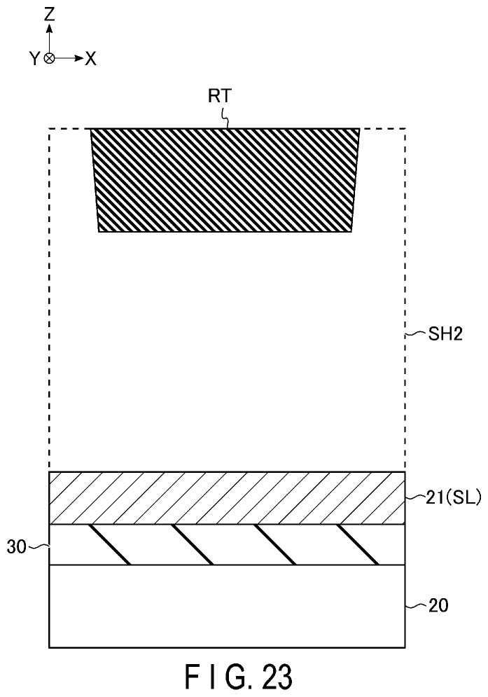

Then, in S7 of FIG. 10, as illustrated in FIGS. 22 and 23, the sacrificial member 70 is removed.

More specifically, the sacrificial member 70 is selectively removed from an upper surface of the laminated body by, for example, wet etching. In the wet etching, the bridge portions RT are not removed. Through such processing, slits SH2 corresponding to the region from which the sacrificial member 70 has been removed are formed. The sacrificial member 70 below the bridge portions RT can be removed by, for example, a chemical solution going around from regions sandwiching the bridge portions RT in the X direction.

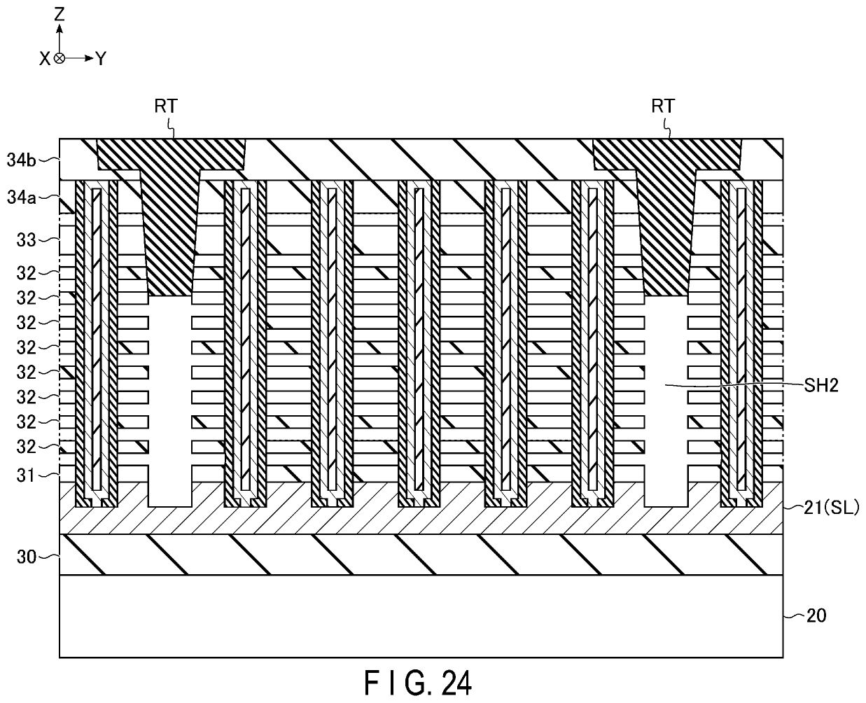

Then, in S8 of FIG. 10, as illustrated in FIG. 24, the sacrificial members 60 to 62 are removed.

More specifically, for example, the sacrificial members 60 to 62 are selectively removed through the slits SH2 by wet etching with hot phosphoric acid. In the wet etching, the bridge portions RT are not removed. After the process of S7 and before the process of S8, a side surface of the sacrificial member 62 and side surfaces of the two sacrificial members 61 associated with the word lines WL6 and WL7 include a portion in contact with the bridge portion RT. As a result, the sacrificial member 62 and the two sacrificial members 61 associated with the word lines WL6 and WL7 include a portion closed by the bridge portion RT. A portion of the sacrificial members 61 and 62 closed by the bridge portion RT can be removed by a chemical solution going around from portions of the slits SH2 sandwiching the bridge portion RT in the X direction, for example, in the XY plane. Through the above processing, a space is formed in a region where the conductor layers 22 to 24 are to be formed. A structure from which the sacrificial members 60 to 62 have been removed is maintained by, for example, the plurality of memory pillars MP and bridge portions RT.

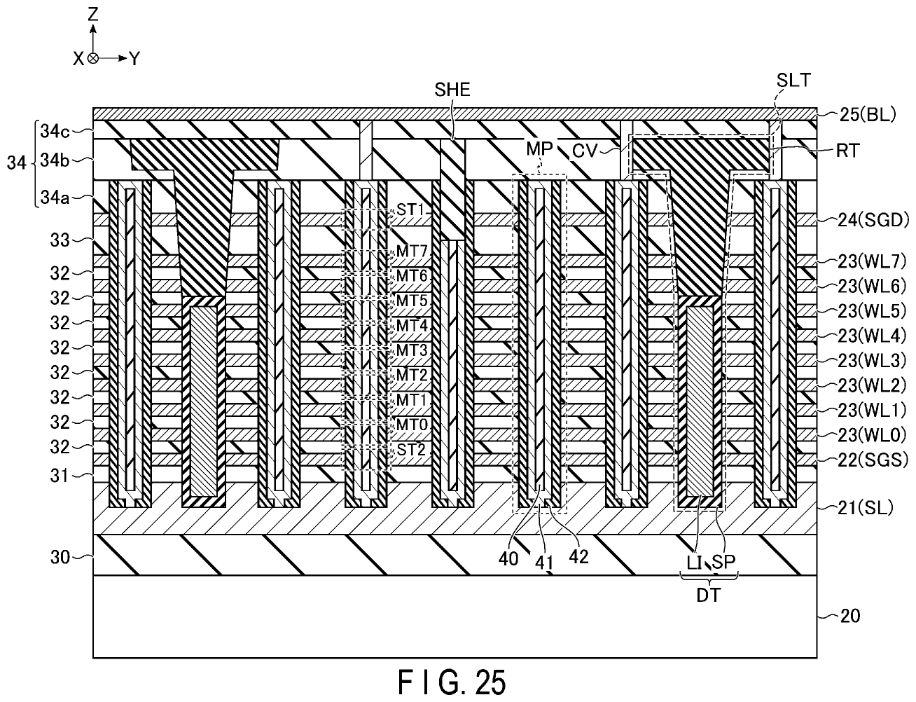

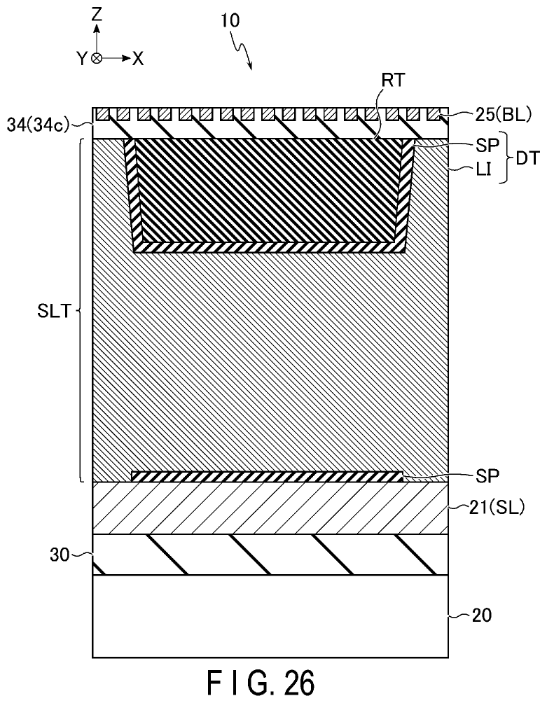

Next, in S9 of FIG. 10, as illustrated in FIGS. 25 and 26, the laminated wiring, the division portion DT of the member SLT, the member SHE, and the contact CV are formed.

First, the conductor is embedded in the spaces from which the sacrificial members 60 to 62 have been removed through the slits SH2. Thereafter, the conductor formed inside the slits SH2 is removed by etch-back processing. As a result, the conductor layer 22 functioning as the select gate line SGS, the plurality of conductor layers 23 functioning as the word lines WL0 to WL7, and the conductor layer 24 functioning as the select gate line SGD are formed.

In this step, for example, after the insulator RW2 containing a metal oxide has been formed along a space in which the conductor layers 22 to 24 are to be formed, the conductor is embedded to form the conductor layers 22 to 24. In addition, the conductor to be embedded is formed, for example, by embedding the conductor 51a after the conductor 51b has been formed. Through the above process, for example, metal oxide contained in the insulator RW2 and the conductive material contained in the conductor layers 22 to 24 may remain between the bridge portion RT and the division portion DT without being completely removed. Therefore, the insulator RW1 and the conductor 50 can be formed.

In the following description, the process of S8 and the process of forming the conductor layers 22 to 24 in the process of S9 are also simply referred to as a replacement processing.

Then, the division portion DT is formed in each slit SH2 after the conductor layers 22 to 24 have been formed.

More specifically, after the conductor layers 22 to 24 have been formed, the spacer SP is formed so as to cover, for example, the side surface and the bottom of the slit SH2 and the side surface and the lower surface of the bridge portion RT. The spacer SP formed at the bottom of the slit SH2 is partially removed from the bottom in the region sandwiching the bridge portion RT in the X direction in FIG. 26 by anisotropic etching, and processed so that a part of the conductor layer 21 is exposed to the slit SH2. Then, the conductor is embedded in the slit SH2 to form the contact LI. Here, the conductor formed outside the slit SH2 is removed by, for example, CMP. When the contact LI is an insulator, anisotropic etching on the spacer SP formed at the bottom of the slit SH2 can be omitted.

Then, a member SHE that divides each block BLK into a plurality of string units SU is formed.

Next, the insulator layer 34c is formed on an upper surface of the insulator layer 34b, an upper surface of the member SLT, and an upper surface of the member SHE. As a result, the insulator layer 34 including the insulator layers 34a, 34b, and 34c is formed. Then, the contact CV is provided so as to be in contact with the semiconductor layer 41 of the memory pillar MP. The contact CV coupled to the memory pillar MP adjacent to the bridge portion RT in the Y direction is formed such that the side surface of the contact CV is in contact with a portion of the bridge portion RT. Then, the conductor layer 25 functioning as the bit line BL is formed on the upper surface of the insulator layer 34c and the upper surface of the contact CV.

The laminated wiring structure and the plurality of members SLT and SHE included in the memory cell array 10 are formed by the method for manufacturing the semiconductor memory device 1 according to the first embodiment described above.

Note that the manufacturing method described above is merely an example, and is not limited thereto. Other processes may be inserted between the respective manufacturing processes, or some processes may be omitted or integrated. In addition, the order of each manufacturing process may be changed within a range in which no problem occurs.

### 1.3 Effect

According to the first embodiment, a decrease in the yield of the semiconductor memory device 1 can be suppressed. Effects of the first embodiment will be described below.

According to the first embodiment, in the semiconductor memory device 1, the member SLT includes the division portion DT extending in the X direction and the plurality of bridge portions RT provided apart from each other in the X direction at the upper end of the member SLT. The lower surface of the bridge portion RT is positioned below the upper surface of the conductor layer 24 corresponding to the select gate line SGD. As a result, an inclination (Incline) of the laminated body that may occur at the time of forming the conductor layers 22 to 24 in the manufacturing process is suppressed. In the Y direction, the width w1 of the upper surface of the bridge portion RT is wider than the width of the lower surface of the bridge portion RT and the width w2 of the division portion DT. As a result, when the bridge portion RT is formed in the manufacturing process, formation of defects called voids, seams, or the like in the bridge portion RT is suppressed. Therefore, a decrease in the strength of the semiconductor memory device 1 is also suppressed. From these, a decrease in the yield of the semiconductor memory device 1 is suppressed.

To supplement, in each block BLK, the structure in the YZ plane of the semiconductor memory device 1 may be asymmetric. For example, in each block BLK, a distance between the memory pillar MP of the first column counted from one end side in the Y direction and the member SLT on one end side in the Y direction may be different from a distance between the memory pillar MP of the first column counted from the other end side in the Y direction and the member SLT on the other end side in the Y direction. As a result, an arrangement of the memory pillars MP and the members SHE in each block BLK in the YZ plane may become asymmetric. In such a case, for example, when the replacement processing from the sacrificial members 60 to 62 to the conductor layers 22 to 24 is performed, a relatively large stress is generated along the Y direction due to the asymmetric arrangement. For this reason, there is a possibility that collapse and destruction of the laminated body may occur as the laminated body tilts due to the stress along the Y direction.

According to the first embodiment, the lower surface of the bridge portion RT is located below the upper surface of the conductor layer 24 corresponding to the select gate line SGD. Such a configuration makes it possible to make the bridge portion RT thicker than when the lower surface of each bridge portion RT is positioned at a height equal to or higher than the upper surface of the conductor layer 24 without changing the aspect ratio of the contact CV, the member SHE, and the like. As a result, a structure from which the sacrificial members 60 to 62 are removed can be made sturdy in the replacement processing as compared with the case where the lower surface of each bridge portion RT is positioned at a height equal to or higher than the upper surface of the conductor layer 24. Therefore, the inclination of the laminated body generated at the time of forming the conductor layers 22 to 24 is suppressed.

According to the first embodiment, the width w1 of the upper surface of the bridge portion RT is larger than the width of the lower surface of the bridge portion RT and the width w2 of the division portion DT. With such a configuration, when the bridge portion RT is formed in the manufacturing process, difficulty in embedding the insulator in the slits SH1 is suppressed. That is, even if the thickness of each of the bridge portions RT is increased in order to suppress the inclination of the laminated body, the formation of defects called voids, seams, and the like in the bridge portions RT can be suppressed. This makes it possible to suppress a decrease in the strength of the semiconductor memory device 1 while suppressing the inclination of the laminated body.

According to the first embodiment, the bridge portion RT includes a first bridge portion RT1 and a second bridge portion RT2. The second bridge portion RT2 has a tapered shape in which a width of the second bridge portion RT2 increases from the lower side to the upper side in the Y direction. Even with such a configuration, difficulty in embedding the insulator in the slits SH1 when the bridge portion RT is formed in the manufacturing process is suppressed.

According to the first embodiment, the bridge portion RT is provided so as to overlap the memory pillar MP when viewed from above. With such a configuration, an increase in the chip size is suppressed while securing the size of the bridge portion RT.

### 2 Modification of First Embodiment

The above-described first embodiment can be variously modified. Hereinafter, a semiconductor memory device according to a modification of the first embodiment will be described.

### 2.1 First Modification of First Embodiment

In the first embodiment described above, the case where the bridge portion RT is not in contact with the memory pillar MP has been described, but is not limited to the configuration. The bridge portion RT may be in contact with the memory pillar MP. In the following description, a configuration and a manufacturing method for the semiconductor memory device 1 according to the first modification of the first embodiment will be mainly described with respect to points different from the configuration and the manufacturing method for the semiconductor memory device 1 according to the first embodiment.

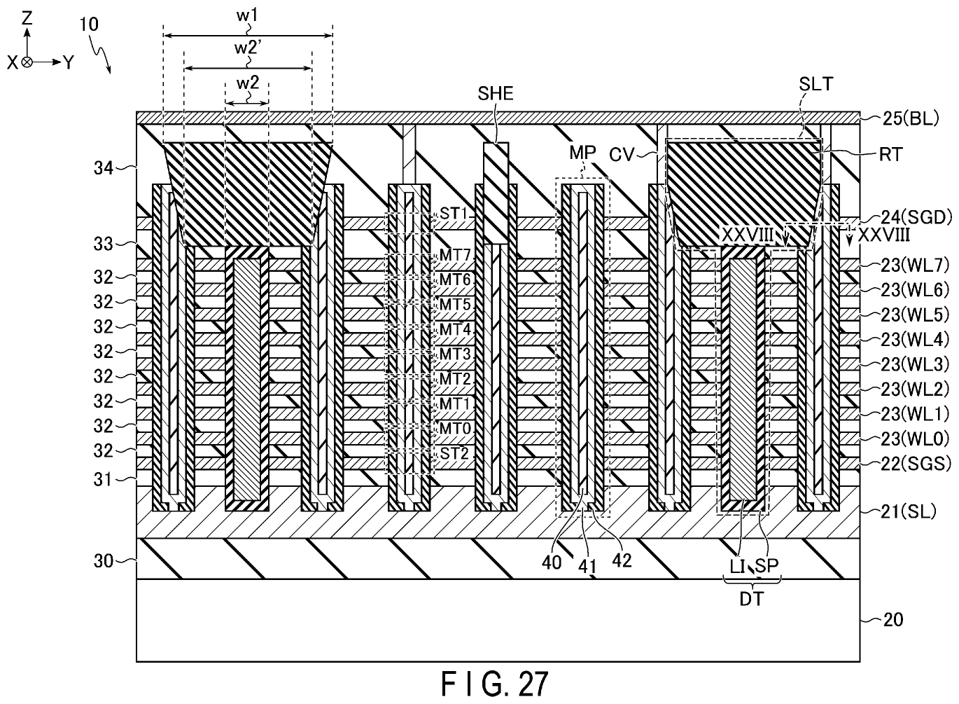

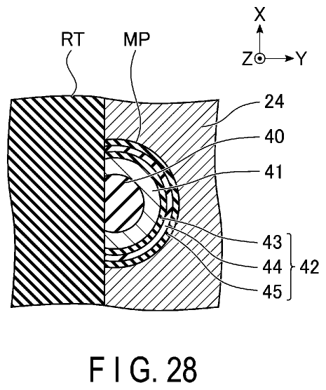

A cross-sectional structure of a semiconductor memory device 1 according to the first modification of the first embodiment will be described with reference to FIGS. 27 and 28. FIG. 27 is a cross-sectional view illustrating an example of a cross-sectional structure in a YZ plane of a memory cell array included in a semiconductor memory device according to the first modification of the first embodiment. FIG. 27 corresponds to the cross-sectional structure of the semiconductor memory device illustrated in FIG. 5. FIG. 28 is a cross-sectional view taken along line XXVIII-XXVIII of FIG. 27, illustrating an example of a cross-sectional structure of a memory pillar of the memory cell array included in the semiconductor memory device according to the first modification of the first embodiment.

In the first modification of the first embodiment, the structures of the semiconductor substrate 20, the conductor layers 21 to 25, the insulator layers 30 to 34, the members SHE, the contacts CV, the memory pillars MP, and the division portions DT are substantially equivalent to the structures of the semiconductor substrate 20, the conductor layers 21 to 25, the insulator layers 30 to 34, the members SHE, the contacts CV, the memory pillars MP, and the division portions DT in the first embodiment. Hereinafter, the structure of the bridge portions RT of the first modification of the first embodiment will be mainly described.

In the cross section illustrated in FIG. 27, as illustrated on the other end side in a Y direction, in a region not including contacts CV coupled to two memory pillars MP sandwiching a member SLT, a bridge portion RT has, for example, a tapered shape in which a width of the bridge portion RT along the Y direction increases from a lower side to an upper side. A lower surface of the bridge portion RT has a width w2′. In the Y direction, the width w2′ of the lower surface of the bridge portion RT is wider than a width w2 of the division portion DT and narrower than a width w1 of an upper surface of the bridge portion RT. In addition, in the first modification of the first embodiment, the width w2′ of the lower surface of the bridge portion RT is equal to or larger than a distance d between the two memory pillars MP sandwiching the member SLT. As a result, the bridge portion RT is in contact with an upper end portion of the memory pillar MP over an entire range along a Z direction below the upper surface of the memory pillar MP. The width w2′ of the lower surface of the bridge portion RT may be narrower than the distance d between the two memory pillars MP sandwiching the member SLT. That is, the bridge portion RT may not be in contact with the upper end portion of the memory pillar MP over the entire range along the Z direction below the upper surface of the memory pillar MP, and at least a portion of the bridge portion RT may be in contact with the upper end portion of the memory pillar MP.

In addition, the lower surface of the bridge portion RT is located below an upper surface of the conductor layer 24 and above an upper surface of the uppermost conductor layer 23. As a result, even if the bridge portion RT and the upper end portion of the memory pillar MP are in contact with each other as described above, a periphery of the memory pillar MP can be surrounded by the laminated wiring at the portion intersecting the conductor layer 23, and deterioration of the function of the memory cell transistor MT included in each memory pillar MP is suppressed.

As illustrated on one end side in the Y direction, in a region including the contacts CV coupled to the two memory pillars MP sandwiching the member SLT, the upper end of the bridge portion RT is in contact with, for example, the contacts CV. For this reason, an upper end portion of the bridge portion RT has a rectangular shape in which a cross-sectional structure of the XY plane is partially missing due to, for example, the contacts CV. On the other hand, the lower end portion of the bridge portion RT is separated from the contacts CV. The bridge portion RT has a tapered shape in which a width of the bridge portion RT along the Y direction increases from the lower side to the upper side. The upper end of the bridge portion RT may not be in contact with the contacts CV.

As described above, the bridge portion RT has a portion in contact with the upper end portion of the memory pillar MP. Therefore, the upper end portion of the memory pillar MP in contact with the bridge portion RT has, for example, a semicircular cross section as illustrated in FIG. 28. The cross section of the upper end portion of the memory pillar MP in contact with the bridge portion RT may not have a semicircular shape in the XY plane. The upper end portion of the memory pillar MP in contact with the bridge portion RT may have a shape in which at least a part of the cross section of the memory pillar MP in a portion not in contact with the bridge portion RT is missing.

In the method for manufacturing the semiconductor memory device 1 according to the first modification of the first embodiment, the bridge portion RT can be formed by, for example, one-step etching process. That is, instead of the processes of S4 and S5 described in FIGS. 15 to 19 of the first embodiment, for example, one-step etching process using the mask M1 can be performed.

Other processes in the method for manufacturing the semiconductor memory device 1 can be the same as those in the first embodiment.

The first modification of the first embodiment also achieves effects similar to those of the first embodiment.

### 2.2 Second Modification of First Embodiment

In the first modification of the first embodiment described above, the case where the lower surface of the bridge portion RT is located above the upper surface of the uppermost conductor layer 23 has been described, but is not limited to the configuration. The lower surface of the bridge portion RT may be located at a height equal to or lower than the upper surface of the uppermost conductor layer 23 while the bridge portion RT is in contact with the memory pillar MP above the upper surface of the uppermost conductor layer 23. In the following description, a configuration of a semiconductor memory device 1 according to a second modification of the first embodiment will be mainly described with respect to differences from the configurations of the semiconductor memory device 1 according to the first embodiment and the first modification of the first embodiment. Note that the method for manufacturing the semiconductor memory device 1 according to the second modification of the first embodiment can be similar to the method for manufacturing the semiconductor memory device 1 according to the first modification of the first embodiment.

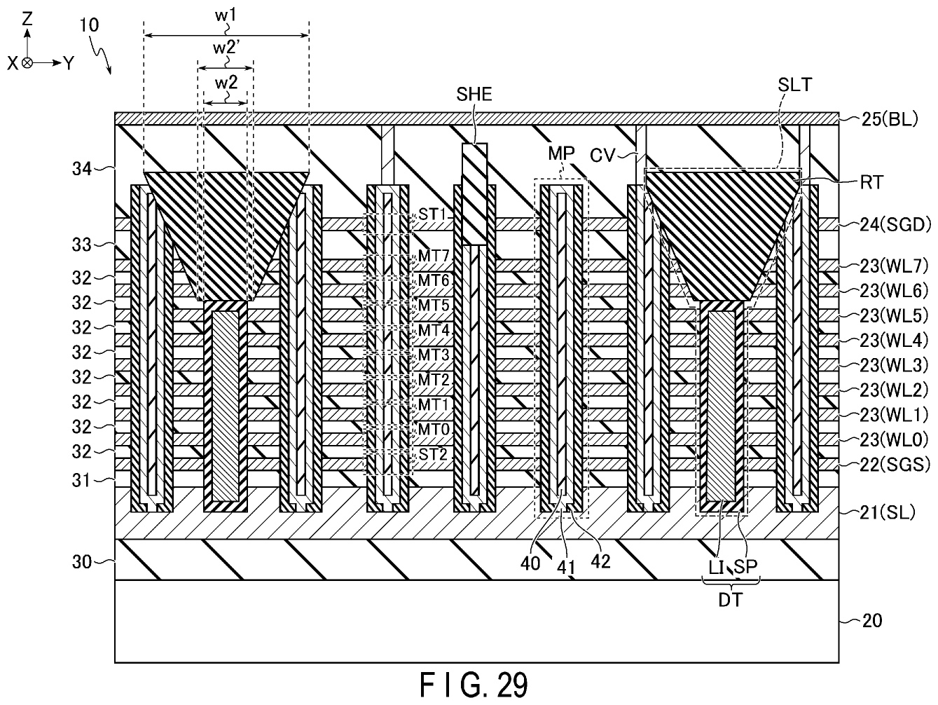

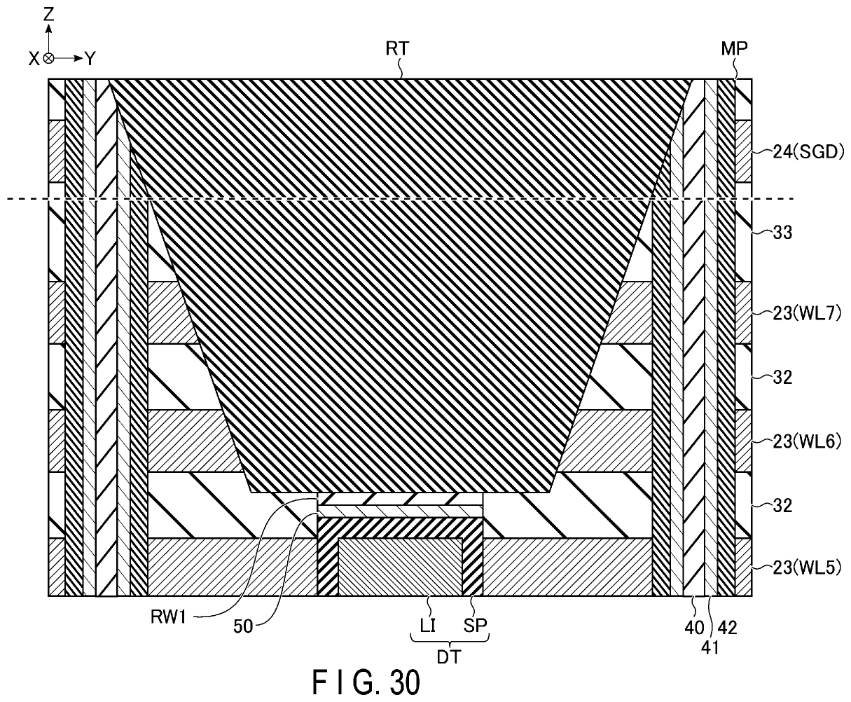

A cross-sectional structure of the semiconductor memory device 1 according to the second modification of the first embodiment will be described with reference to FIGS. 29 and 30. FIGS. 29 and 30 are cross-sectional views illustrating an example of a cross-sectional structure in a YZ plane of a memory cell array included in the semiconductor memory device according to the second modification of the first embodiment. FIG. 29 corresponds to the cross-sectional structure of the semiconductor memory device illustrated in FIGS. 5 and 27. FIG. 30 shows an enlarged view of the vicinity of the bridge portion RT in the cross-sectional structure shown in FIG. 29.

In the second modification of the first embodiment, structures of a semiconductor substrate 20, conductor layers 21 to 25, insulator layers 30 to 34, members SHE, contacts CV, memory pillars MP, and division portions DT are substantially equivalent to the structures of the semiconductor substrate 20, the conductor layers 21 to 25, the insulator layers 30 to 34, the members SHE, the contacts CV, the memory pillar MP, and the division portions DT in the first modification of the first embodiment. Hereinafter, a structure of the bridge portion RT of the second modification of the first embodiment will be mainly described.

A lower surface of the bridge portion RT is located at a height equal to or lower than an upper surface of the uppermost conductor layer 23. In the cross section illustrated in FIG. 29, the lower surface of the bridge portion RT is located between the upper surface of the conductor layer 23 corresponding to a word line WL5 and a lower surface of the conductor layer 23 corresponding to a word line WL6.

As illustrated in FIG. 30, an upper end portion of the bridge portion RT in contact with the memory pillar MP is not included in a range below the upper surface of the uppermost conductor layer 23, but is included in a layer higher than the upper surface of the uppermost conductor layer 23. In addition, in the YZ plane, the lower end portion of the bridge portion RT separated from the memory pillar MP is provided so as to divide the wiring layer included between the two memory pillars MP sandwiching the member SLT. With such a configuration, even in the two memory pillars MP sandwiching the member SLT, a periphery of the memory cell transistor MT included in the same layer as the bridge portion RT can be surrounded by the laminated wiring. As a result, a decrease in the function of the memory cell transistor MT is suppressed.

The second modification of the first embodiment also achieves effects similar to those of the first embodiment and the first modification of the first embodiment.

### 2.3 Third Modification of First Embodiment

In the first embodiment, the first modification of the first embodiment, and the second modification of the first embodiment described above, the case where the lower surface of the bridge portion RT is located below the upper surface of the conductor layer 24 has been described, but is not limited to the configuration. The lower surface of the bridge portion RT may be positioned at a height equal to or higher than the upper surface of the conductor layer 24. In the following description, a configuration of the semiconductor memory device 1 according to the third modification of the first embodiment will be mainly described with respect to differences from the configurations of the semiconductor memory device 1 according to the first embodiment, the first modification of the first embodiment, and the second modification of the first embodiment. Note that the method for manufacturing the semiconductor memory device 1 according to the third modification of the first embodiment can be similar to the method for manufacturing the semiconductor memory device 1 according to the first modification of the first embodiment and the second modification of the first embodiment.

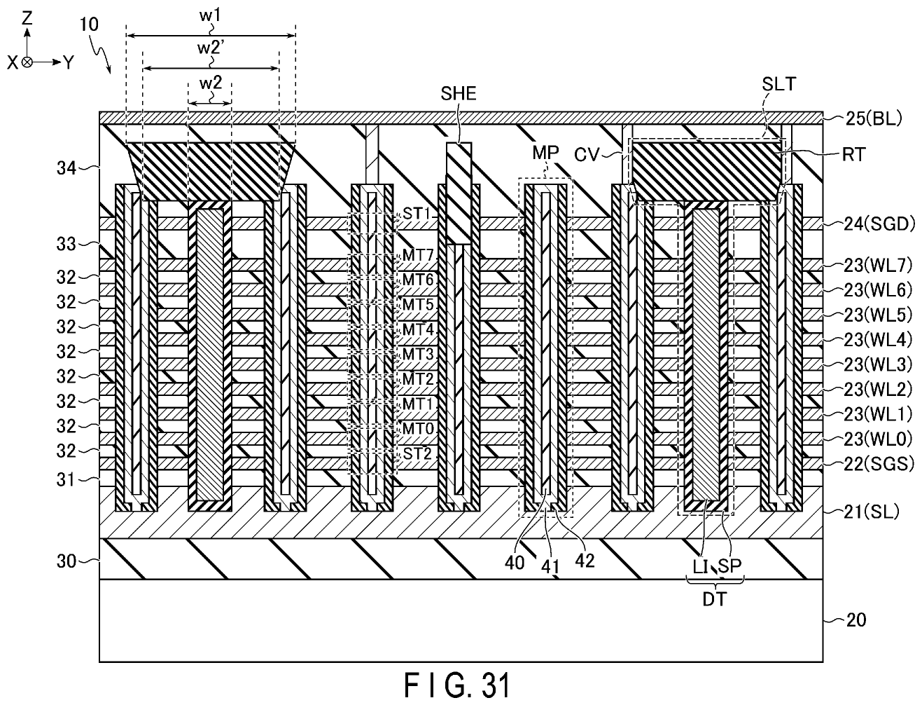

A cross-sectional structure of a semiconductor memory device 1 according to a third modification of the first embodiment will be described with reference to FIG. 31. FIG. 31 is a cross-sectional view illustrating an example of the cross-sectional structure in a YZ plane of a memory cell array included in the semiconductor memory device according to the third modification of the first embodiment. FIG. 31 corresponds to the cross-sectional structure of the semiconductor memory device illustrated in FIGS. 5, 27, and 29.

In the third modification of the first embodiment, structures of a semiconductor substrate 20, conductor layers 21 to 25, insulator layers 30 to 34, members SHE, contacts CV, memory pillars MP, and division portions DT are substantially equivalent to the structures of the semiconductor substrate 20, the conductor layers 21 to 25, the insulator layers 30 to 34, the members SHE, the contacts CV, the memory pillars MP, and the division portions DT in the first modification of the first embodiment and the second modification of the first embodiment. Hereinafter, the structure of the bridge portions RT in the third modification of the first embodiment will be mainly described.

A lower surface of each bridge portion RT is lower than an upper surface of the memory pillar MP and is located at a height equal to or higher than an upper surface of the conductor layer 24. The bridge portion RT has a portion in contact with the memory pillars MP and the contacts CV. As a result, the memory pillar MP in contact with the bridge portion RT includes, for example, a portion having a semicircular XY plane at an upper end portion of the memory pillar MP, as in the first modification of the first embodiment and the second modification of the first embodiment.

As illustrated on the other end side in the Y direction, in a region not including the contacts CV coupled to the two memory pillars MP sandwiching the member SLT, the bridge portion RT has a tapered shape in which a width of the bridge portion RT along the Y direction increases from a lower side to an upper side, similarly to the first modification of the first embodiment and the second modification of the first embodiment.

In addition, as illustrated on one end side in the Y direction, in the region including the contacts CV coupled to the two memory pillars MP sandwiching the member SLT, the bridge portion RT includes an upper end portion having a rectangular shape in which, for example, a portion is missing in the cross-sectional structure in the XY plane by being in contact with the contacts CV, similarly to the first modification of the first embodiment and the second modification of the first embodiment. The upper end portion of the bridge portion RT may not be in contact with the contacts CV. In addition, FIG. 31 illustrates a case where the bridge portion RT is in contact with the memory pillar MP over the entire lower end portion along the Z direction, but is not limited to the configuration. The bridge portion RT may be separated from the memory pillar MP at a position of the lower surface of the bridge portion RT without being in contact with the memory pillar MP over the entire lower end portion along the Z direction.

According to the third modification of the first embodiment, in a region not including the contacts CV coupled to the two memory pillars MP sandwiching the member SLT in the YZ plane, the bridge portion RT has a tapered shape in which the width of the bridge portion RT in the Y direction increases from the lower side to the upper side. With such a configuration and other configurations, a decrease in the strength of the semiconductor memory device 1 can be suppressed while suppressing the inclination of the laminated body also in the third modification of the first embodiment, similarly to the first embodiment, the first modification of the first embodiment, and the second modification of the first embodiment. As a result, a decrease in a yield of the semiconductor memory device 1 can be suppressed.

Also, in the third modification of the first embodiment, similarly to the first embodiment, the first modification of the first embodiment, and the second modification of the first embodiment, an increase in a chip size is suppressed while securing a size of the bridge portion RT.

### 2.4 Fourth Modification of First Embodiment

In the first embodiment, the first modification of the first embodiment, the second modification of the first embodiment, and the third modification of the first embodiment, the case where the width w1 of the bridge portion RT along the Y direction is equal to or larger than the distance d between the two memory pillars MP sandwiching the member SLT has been described, but is not limited to the configuration. A width w1 of a bridge portion RT along the Y direction may be narrower than a distance d between two memory pillars MP sandwiching a member SLT. In the following description, a configuration of a semiconductor memory device 1 according to the fourth modification of the first embodiment will be mainly described with respect to differences from the configurations of the semiconductor memory device 1 according to the first embodiment, the first modification of the first embodiment, the second modification of the first embodiment, and the third modification of the first embodiment. Note that the method for manufacturing the semiconductor memory device 1 according to the fourth modification of the first embodiment can be similar to the method for manufacturing the semiconductor memory device 1 according to the first modification of the first embodiment, the second modification of the first embodiment, and the third modification of the first embodiment.

A configuration of the semiconductor memory device 1 according to the fourth modification of the first embodiment will be described.

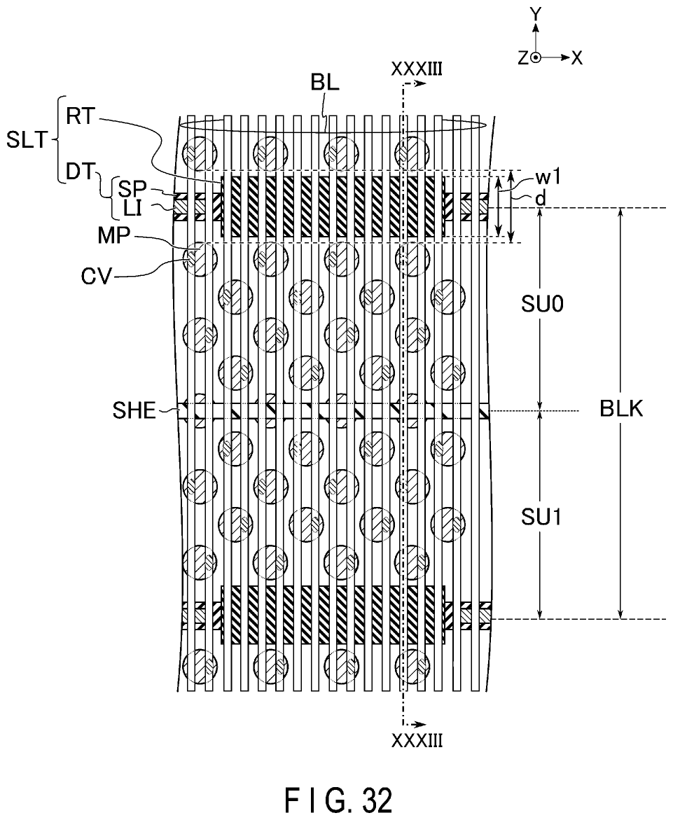

A planar structure of a memory cell array 10 will be described with reference to FIG. 32. FIG. 32 is a plan view illustrating an example of a planar layout of a memory cell array included in the semiconductor memory device according to the fourth modification of the first embodiment. FIG. 32 mainly illustrates a structure included in one block BLK. FIG. 32 corresponds to FIG. 4 of the first embodiment.

In a plane illustrated in FIG. 32, the structure of the semiconductor memory device 1 according to the fourth modification of the first embodiment is similar to the structures of the semiconductor memory devices according to the first embodiment, the first modification of the first embodiment, the second modification of the first embodiment, and the third modification of the first embodiment except for a structure of bridge portions RT.

When viewed from above, a width w1 of bridge portions RT is narrower than a distance d between two memory pillars MP sandwiching a member SLT in a Y direction. As a result, the bridge portion RT does not overlap the memory pillar MP when viewed from above. Therefore, the bridge portion RT is not in contact with the memory pillars MP.

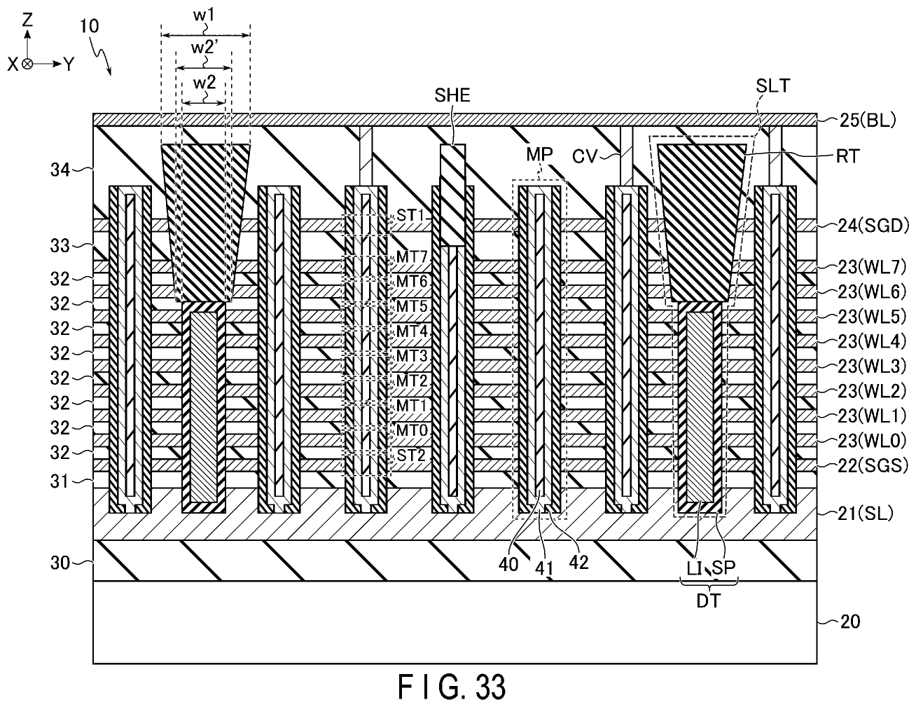

A cross-sectional structure of the semiconductor memory device 1 according to the fourth modification of the first embodiment will be described with reference to FIG. 33. FIG. 33 is a cross-sectional view taken along line XXXIII-XXXIII of FIG. 32, illustrating an example of a cross-sectional structure in a YZ plane of the memory cell array included in the semiconductor memory device according to the fourth modification of the first embodiment. FIG. 33 corresponds to the cross-sectional structure of the semiconductor memory device illustrated in FIGS. 5, 27, 29, and 31.

In the fourth modification of the first embodiment, structures of a semiconductor substrate 20, conductor layers 21 to 25, insulator layers 30 to 34, members SHE, contacts CV, division portions DT, and memory pillars MP are substantially equivalent to the structures of the semiconductor substrate 20, the conductor layers 21 to 25, the insulator layers 30 to 34, the members SHE, the contacts CV, the division portions DT, and the memory pillars MP in the first embodiment. Hereinafter, differences from the first embodiment will be mainly described with respect to the structure of the bridge portions RT of the fourth modification of the first embodiment.

As described above, the bridge portions RT do not overlap the memory pillars MP when viewed from above. As a result, the bridge portions RT and the memory pillars MP are not in contact with each other. The bridge portions RT is not in contact with the contacts CV. The structure of the bridge portions RT has, for example, a tapered shape in which a width of the bridge portion RT along the Y direction increases from a lower side to an upper side.

Also, in the fourth modification of the first embodiment, a decrease in a yield of the semiconductor memory device 1 can be suppressed as in the first embodiment, the first modification of the first embodiment, the second modification of the first embodiment, and the third modification of the first embodiment.

### 3 Second Embodiment

A semiconductor memory device 1 according to a second embodiment will be described. The semiconductor memory device 1 according to the second embodiment is different from the semiconductor memory device 1 according to the first embodiment, the first modification of the first embodiment, the second modification of the first embodiment, the third modification of the first embodiment, and the fourth modification of the first embodiment in that a bridge portion RT has a stepped structure also on one end side and the other end side in an X direction. In the following description, a configuration and a manufacturing method for the semiconductor memory device 1 according to the second embodiment will be mainly described with respect to differences from the configuration and the manufacturing method for the semiconductor memory device 1 according to the first embodiment, the first modification of the first embodiment, the second modification of the first embodiment, the third modification of the first embodiment, and the fourth modification of the first embodiment.

### 3.1 Configuration of Memory Cell Array

The configuration of the semiconductor memory device 1 according to the second embodiment will be described. Note that a planar structure of the semiconductor memory device 1 according to the second embodiment is similar to the planar structure of the semiconductor memory device 1 according to the fourth modification of the first embodiment illustrated in FIG. 32. Hereinafter, the cross-sectional structure of the semiconductor memory device 1 according to the second embodiment will be mainly described.

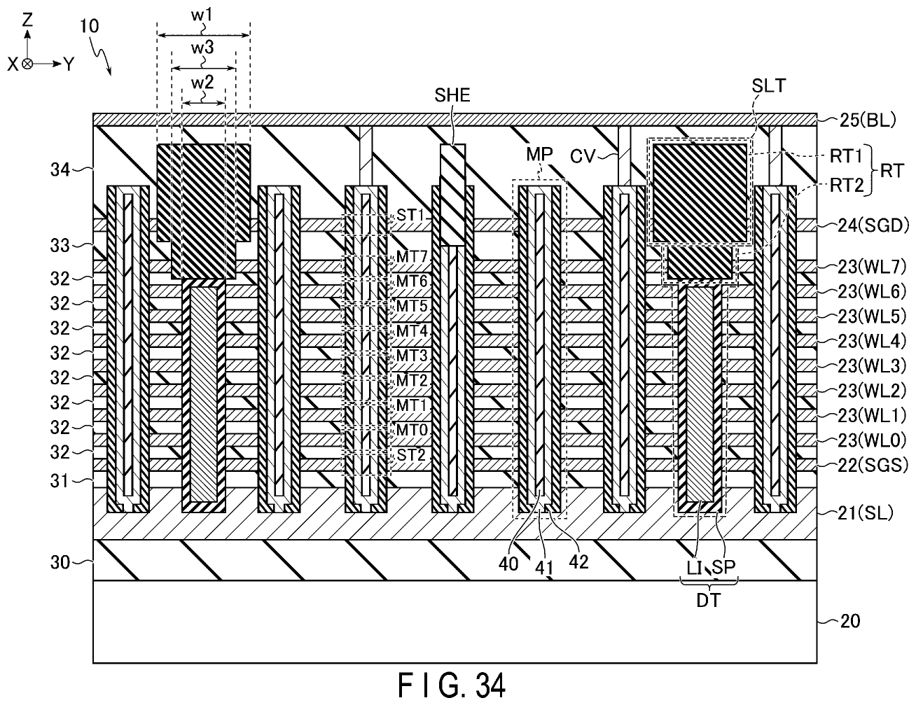

The cross-sectional structure of the semiconductor memory device 1 according to the second embodiment will be described with reference to FIG. 34. FIG. 34 is a cross-sectional view illustrating an example of a cross-sectional structure in a YZ plane of a memory cell array included in the semiconductor memory device according to the second embodiment. FIG. 34 corresponds to the cross-sectional structure of the semiconductor memory device illustrated in FIGS. 5, 27, 29, 31, and 33.

In the second embodiment, the structures of the semiconductor substrate 20, the conductor layers 21 to 25, the insulator layers 30 to 34, the members SHE, the contacts CV, the memory pillars MP, and the division portions DT are substantially the same as the structures of the semiconductor substrate 20, the conductor layers 21 to 25, the insulator layers 30 to 34, the members SHE, the contacts CV, the memory pillars MP, and the division portions DT in the first embodiment and the fourth modification of the first embodiment. Hereinafter, a structure of bridge portions RT of the second embodiment will be described.

Similarly to the first embodiment, the bridge portion RT includes, for example, a first bridge portion RT1 and a second bridge portion RT2. Each of the first bridge portion RT1 and the second bridge portion RT2 has, for example, a rectangular cross-sectional structure in the YZ plane. The first bridge portion RT1 has a width w1 in the Y direction. The second bridge portion RT2 has a width w3 in the Y direction. However, the cross-sectional structures of the first bridge portion RT1 and the second bridge portion RT2 are not limited to rectangular shapes. Similarly to the first embodiment, each of the first bridge portion RT1 and the second bridge portion RT2 may have a tapered shape in which the width along the Y direction increases from the lower side to the upper side.

The lower surface of the bridge portion RT is positioned below the upper surface of the conductor layer 24 corresponding to the select gate line SGD. In FIG. 34, a lower surface of the bridge portion RT is located, for example, between a lower surface of the conductor layer 23 corresponding to a word line WL7 and an upper surface of the conductor layer 23 corresponding to a word line WL6.

In the example shown in FIG. 34, the first bridge portion RT1 has a portion included in a layer lower than the upper surface of the conductor layer 24, but is not limited to the configuration. The first bridge portion RT1 is not included in a layer below the upper surface of the conductor layer 24, and may be provided at a height equal to or higher than the upper surface of the conductor layer 24.

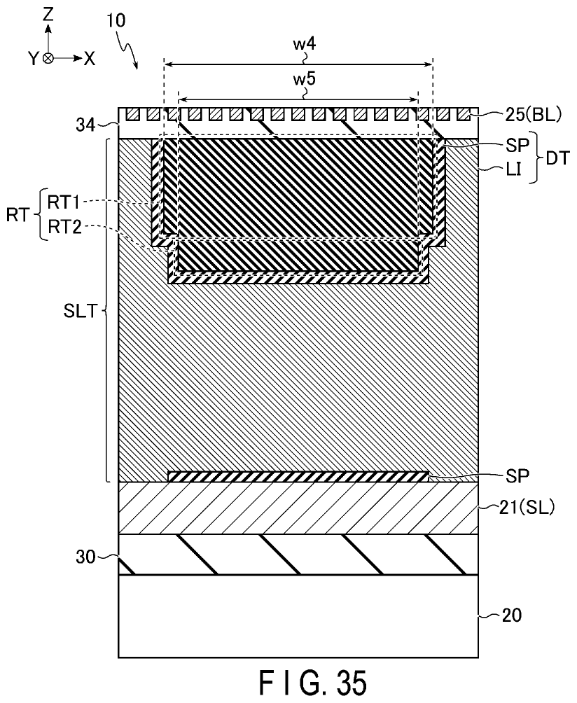

The structure of the bridge portion RT according to the second embodiment will be further described with reference to FIG. 35. FIG. 35 is a cross-sectional view illustrating an example of a cross-sectional structure in a XZ plane of the memory cell array included in the semiconductor memory device according to the second embodiment. FIG. 35 corresponds to the cross-sectional structure of the semiconductor memory device illustrated in FIG. 8. In FIG. 35, illustration of an insulator RW1 and a conductor 50 is omitted.

Each of the first bridge portion RT1 and the second bridge portion RT2 has a rectangular shape even in the cross-sectional structure in the XZ plane, for example. The first bridge portion RT1 has a width w4 in the X direction. The second bridge portion RT2 has a width w5 narrower than the width w4 in the X direction. However, the cross-sectional structures of the first bridge portion RT1 and the second bridge portion RT2 in the XZ plane are not limited to rectangular shapes. Each of the first bridge portion RT1 and the second bridge portion RT2 may have a tapered shape in which the width along the X direction increases from the lower side to the upper side.

With the above configuration, similarly to the cross-sectional structure of the bridge portion RT in the YZ plane shown in FIG. 34, the bridge portion RT also has a convex shape in which the second bridge portion RT2 protrudes downward from the first bridge portion RT1 in the cross-sectional structure in the XZ plane. For this reason, the bridge portion RT also has a stepped structure on one end side and the other end side in the X direction, for example.

### 3.2 Method for Manufacturing Semiconductor Memory Device

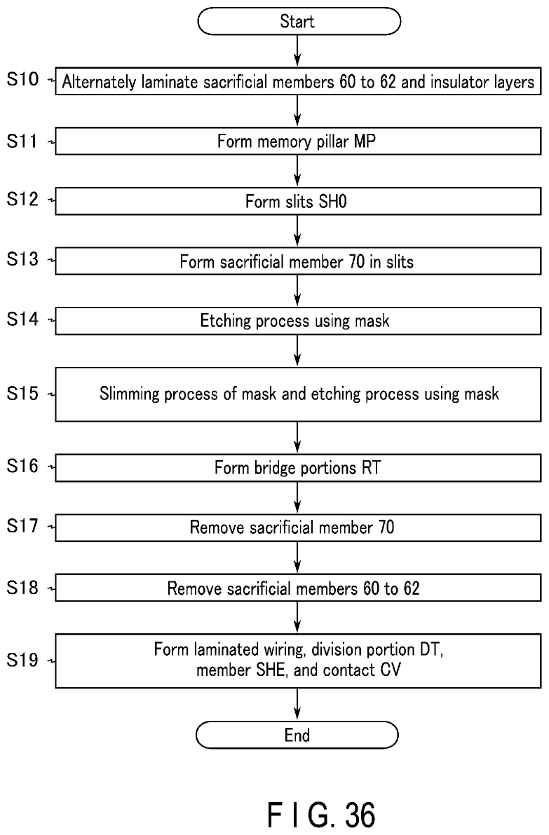

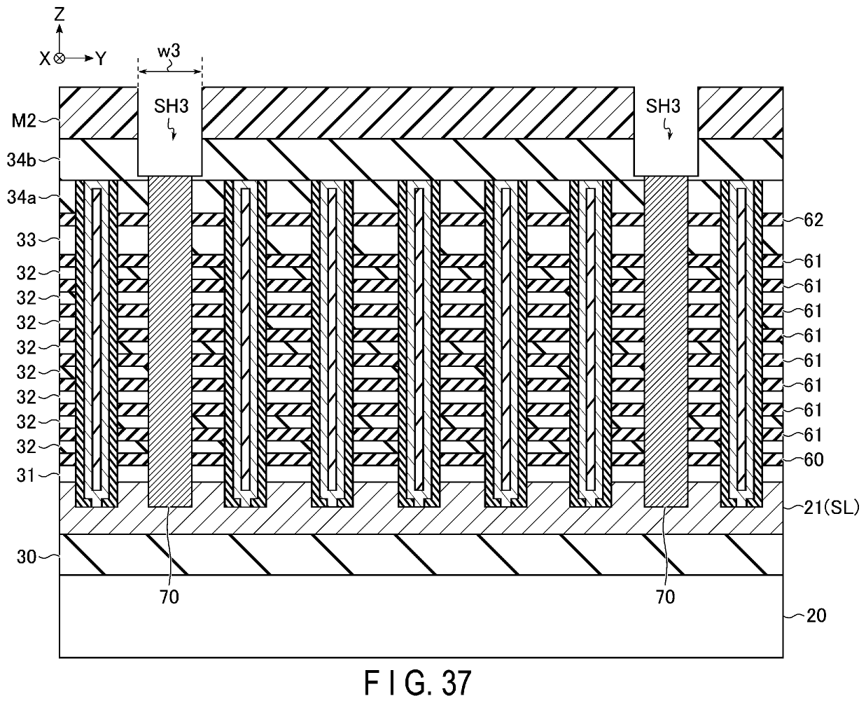

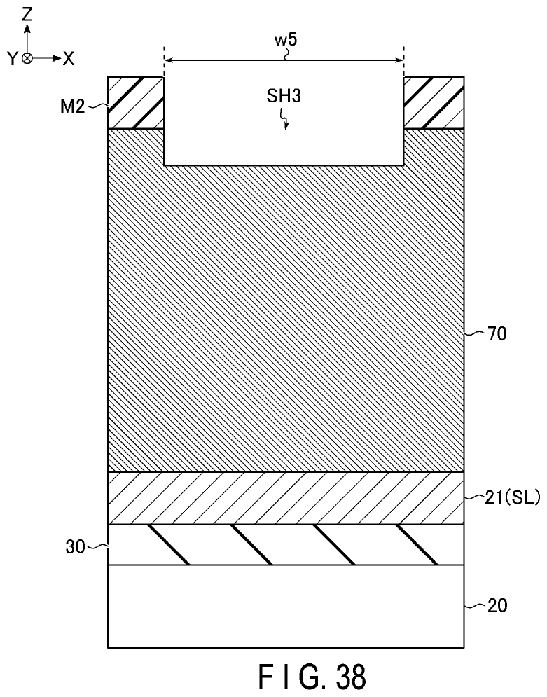

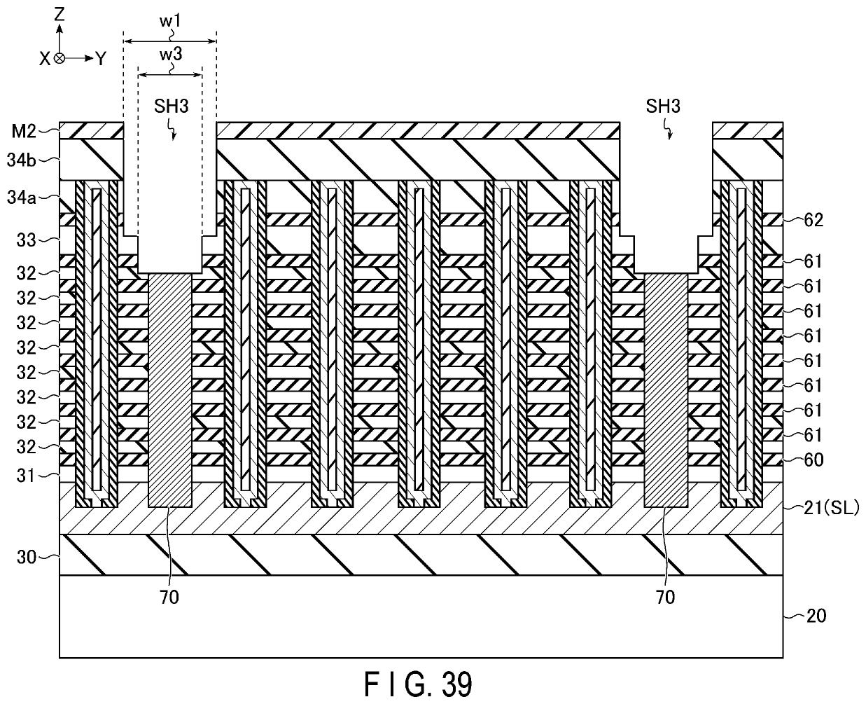

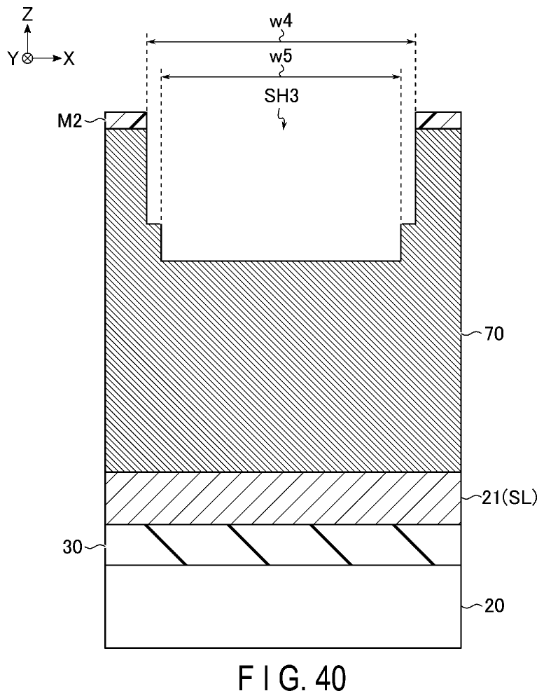

A method for manufacturing the semiconductor memory device 1 according to the second embodiment will be described with reference to FIGS. 36 to 40. FIG. 36 is a flowchart illustrating an example of the method for manufacturing the semiconductor memory device according to the second embodiment. FIGS. 37 to 40 are cross-sectional views illustrating an example of the method for manufacturing the semiconductor memory device according to the second embodiment. The cross-sectional views illustrated in FIGS. 37 and 39 correspond to the region illustrated in FIG. 34. The cross-sectional views illustrated in FIGS. 38 and 40 correspond to the region illustrated in FIG. 35.

As illustrated in FIG. 36, in the method for manufacturing the semiconductor memory device according to the second embodiment, processes of S10 to S19 are sequentially executed. Hereinafter, an example of a method for manufacturing the semiconductor memory device 1 according to the second embodiment will be mainly described with reference to FIG. 36 as appropriate, with processing different from the method for manufacturing the semiconductor memory device 1 according to the first embodiment.

The processes of S10 to S13 in FIG. 36 are similar to the processes of S0 to S3 in the first embodiment.

In S14 of FIG. 36, a process similar to S4 is executed using a mask M2 including a plurality of openings each having a size different from that of the openings ROP in the first embodiment. As a result, as shown in FIGS. 37 and 38, slits SH3 associated with the second bridge portions RT2 are formed. Note that the widths of the openings included in the mask M2 along the X direction and the Y direction are, for example, widths w5 and w3, respectively. In this step, for example, a portion of the sacrificial member 70 and a portion of the insulator layer 34b are removed.

Next, in S15 of FIG. 36, a slimming process of the mask M2 and an etching process using the mask M2 after the slimming process are performed. As a result, as illustrated in FIGS. 39 and 40, a stepped shape in the slit SH3 along the X direction and the Y direction is formed.

More specifically, after the process of S14, isotropic etching process of the mask M2 is executed. As a result, the openings of the mask M2 isotropically expand. The width along the X direction and the width along the Y direction of the isotropic expanding openings are, for example, widths w4 and w1, respectively. Then, anisotropic etching process using the mask M2 having the isotropically widened opening is executed. In this step, anisotropic etching using the mask M2 is performed so that, for example, regions of the sacrificial members 61, 62, and 70 and the insulator layers 32, 33, 34a, and 34b where the bridge portions RT are to be formed are removed. As a result, the slit SH3 having a stepped cross-sectional structure in the XZ plane and the YZ plane is formed in the region where the bridge portion RT is to be formed.

After the process of S15 has been completed, the mask M2 is removed.

The processes of S16 to S19 in FIG. 36 are similar to the processes of S6 to S9 of the first embodiment.

The laminated wiring structure and the plurality of members SLT and SHE included in the memory cell array 10 are formed by the method for manufacturing the semiconductor memory device 1 according to the second embodiment described above.

According to the second embodiment, similarly to the first embodiment, the first modification of the first embodiment, the second modification of the first embodiment, the third modification of the first embodiment, and the fourth modification of the first embodiment, a decrease in yield of the semiconductor memory device 1 can be suppressed.

### 4 Modification of Second Embodiment

The above-described second embodiment can be variously modified. Hereinafter, a semiconductor memory device according to a modification of the second embodiment will be described.

In the second embodiment described above, the case where the lower surface of the bridge portion RT is located below the upper surface of the conductor layer 24 corresponding to the select gate line SGD has been described, but is not limited to the configuration. The lower surface of the bridge portion RT may be positioned at a height equal to or higher than the upper surface of the conductor layer 24. Hereinafter, a structure of a semiconductor memory device 1 according to the modification of the second embodiment will be mainly described with respect to differences from the structure of the semiconductor memory device 1 according to the second embodiment. Note that the method for manufacturing the semiconductor memory device 1 according to the modification of the second embodiment is similar to the method for manufacturing the semiconductor memory device 1 according to the second embodiment.

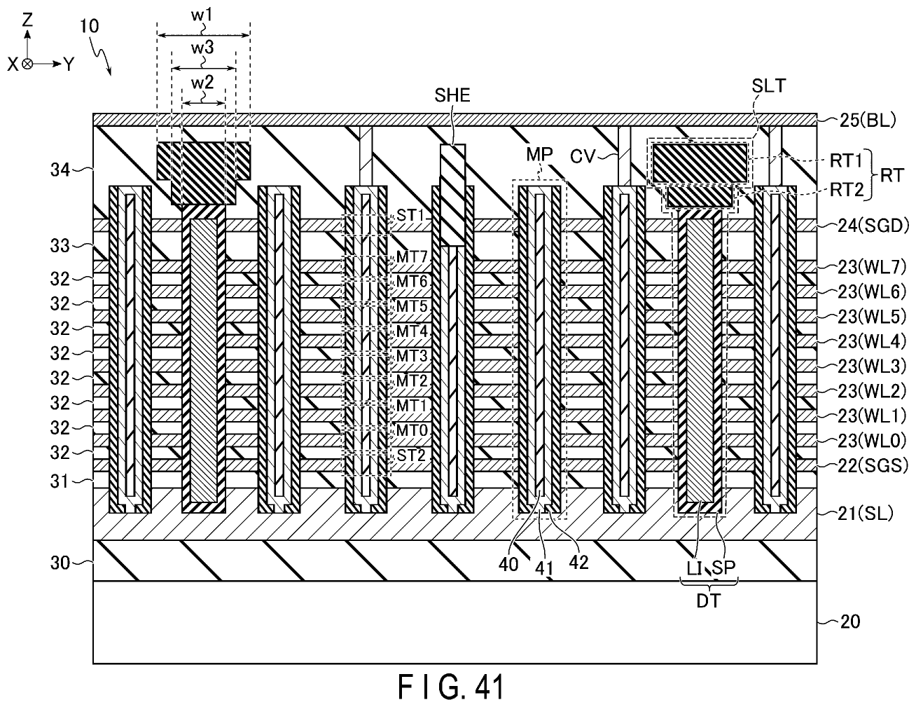

A cross-sectional structure of a semiconductor memory device 1 according to the modification of the second embodiment will be described with reference to FIG. 41. FIG. 41 is a cross-sectional view illustrating an example of a cross-sectional structure in a YZ plane of a memory cell array included in the semiconductor memory device according to the modification of the second embodiment. FIG. 41 corresponds to the cross-sectional structure of the semiconductor memory device illustrated in FIGS. 5, 27, 29, 31, 33, and 34.

A lower surface of a bridge portion RT is positioned at a height equal to or higher than an upper surface of the conductor layer 24, for example.

The cross-sectional structure in the XZ plane is similar to the cross-sectional structure in the XZ plane in the second embodiment except that the height of the lower surface of the bridge portion RT is different.

According to the modification of the second embodiment, the bridge portion RT in which a width w1 of a first bridge portion RT1 is wider than a width w2 of a division portion DT and a width w3 of a second bridge portion RT2 in the Y direction, and the other configurations make it possible to suppress a decrease in a strength of the semiconductor memory device 1 while suppressing the inclination of the laminated body, similarly to the first embodiment, the first modification of the first embodiment, the second modification of the first embodiment, the third modification of the first embodiment, the fourth modification of the first embodiment, and the second embodiment. As a result, a decrease in a yield of the semiconductor memory device 1 can be suppressed.

### 5 Others

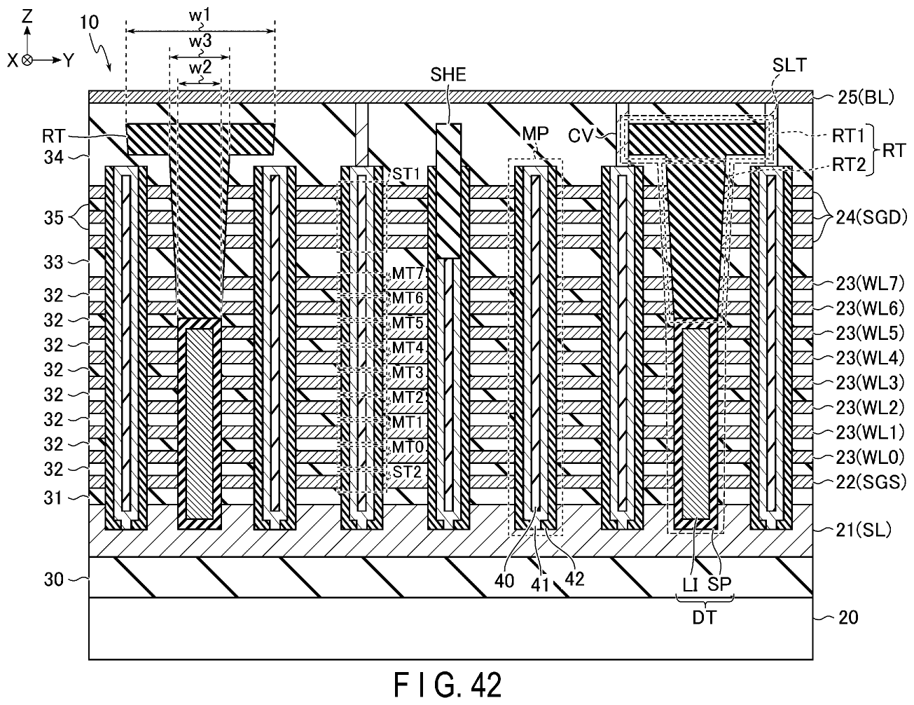

In the first embodiment, the first modification of the first embodiment, the second modification of the first embodiment, the third modification of the first embodiment, the fourth modification of the first embodiment, the second embodiment, and the modification of the second embodiment, the case where one conductor layer 24 corresponding to the select gate line SGD is provided has been described, but is not limited to the configuration. As illustrated in FIG. 42, the select gate line SGD may include a plurality of conductor layers 24. FIG. 42 is a cross-sectional view illustrating an example of a cross-sectional structure in a YZ plane of a memory cell array included in a semiconductor memory device according to another example. FIG. 42 corresponds to a cross-sectional structure of the semiconductor memory device illustrated in FIGS. 5, 27, 29, 31, 33, 34, and 41. In the example illustrated in FIG. 42, three conductor layers 24 and two insulator layers 35 are provided on an upper surface of an insulator layer 33 in the order of the conductor layer 24, the insulator layer 35, the conductor layer 24, the insulator layer 35, and the conductor layer 24. Except for such a configuration, a configuration of the memory cell array 10 of the semiconductor memory device 1 according to the other example illustrated in FIG. 42 is similar to that of the first embodiment.

More specifically, a length in the Y direction of the first conductor layer 24, a second conductor layer 24, and a third conductor layer 24 in this order from a top increases between the bridge portion RT and the memory pillar MP adjacent to the bridge portion RT. A lower surface of the bridge portion RT may be located below an upper surface of the uppermost conductor layer 24 among the plurality of conductor layers 24. The number of layers of the conductor layer 24 is not limited to three, and may be two or four or more.

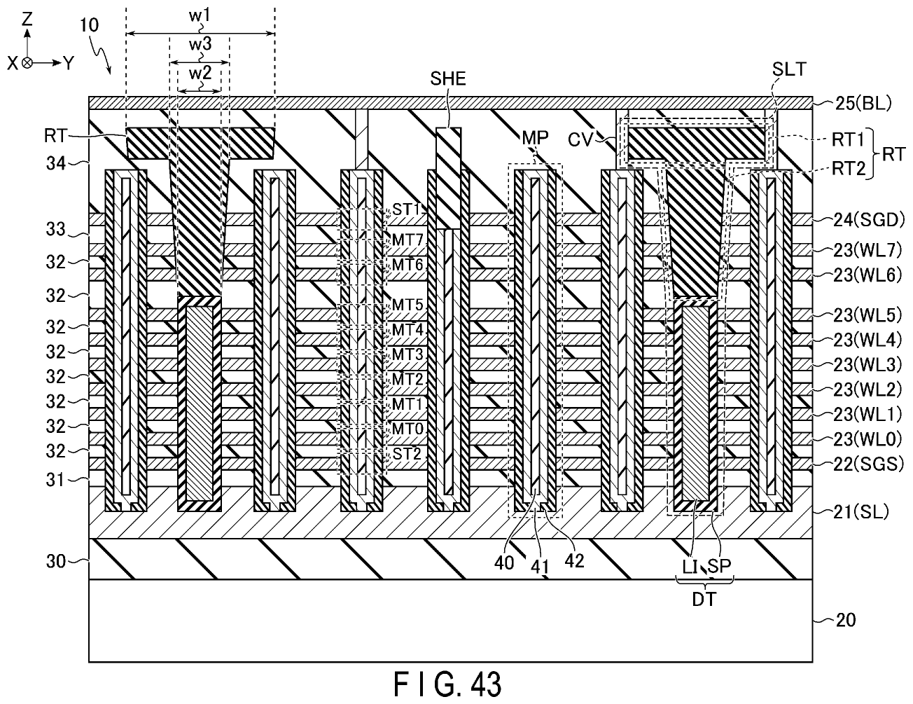

In the first embodiment, the first modification of the first embodiment, the second modification of the first embodiment, the third modification of the first embodiment, the fourth modification of the first embodiment, the second embodiment, the modification of the second embodiment, and the other example illustrated in FIG. 42, the case where the thicknesses of all the insulator layers 32 are equal has been described, but is not limited to the configuration. As illustrated in FIG. 43, when lower surfaces of bridge portions RT are included at the same height as a predetermined insulator layer 32, the predetermined insulator layer 32 may be provided thicker than the other insulator layers 32. FIG. 43 is a cross-sectional view illustrating an example of a cross-sectional structure in a YZ plane of a memory cell array included in a semiconductor memory device according to another example. FIG. 43 corresponds to the cross-sectional structure of the semiconductor memory device illustrated in FIGS. 5, 27, 29, 31, 33, 34, 41, and 42. In the example illustrated in FIG. 43, an insulator layer 32 between the conductor layer 23 corresponding to a word line WL5 and the conductor layer 23 corresponding to a word line WL6 is provided to be thicker than the other insulator layers 32 according to the position of the lower surface of the bridge portion RT. Except for such a configuration, the configuration of the memory cell array 10 of the semiconductor memory device 1 according to the other example illustrated in FIG. 43 is similar to that of the first embodiment.

Note that the semiconductor memory device 1 according to the other examples illustrated in FIGS. 42 and 43 can be combined with the second embodiment and the above-described modifications unless explicitly excluded.

In the above description, the case where the laminated wiring structure of the memory cell array 10 is provided above the semiconductor substrate 20 has been described, but is not limited to the configuration. For example, a circuit such as the row decoder module 15 or the sense amplifier module 16 may be formed on a substrate different from the substrate on which the memory cell array 10 is provided, and the substrate on which the memory cell array 10 is provided may be removed after these substrates are bonded, so that the semiconductor substrate 20 may be located in the upward direction of the laminated wiring structure of the memory cell array 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a plurality of conductor layers provided apart from each other in a first direction perpendicular to a substrate surface and including a first conductor layer as an uppermost layer;
a plurality of memory pillars penetrating the conductor layers and extending in the first direction; and
a member that includes a first portion extending in a second direction in the substrate surface in the conductor layers and a plurality of second portions provided apart from each other in the second direction on the uppermost layer side of the conductor layers, and divides the conductor layers in a third direction orthogonal to the second direction in the substrate surface; wherein
a lower surface of each of the second portions is located below an upper surface of the first conductor layer, and
an upper surface of each of the second portions is wider in a width of the member in the third direction, than the lower surface of each of the second portions and than the first portion.

2. The device of claim 1, wherein
the lower surface of each of the second portions is located below a lower surface of a second conductor layer different from the first conductor layer among the conductor layers, and
in a region sandwiched between one of the second portions and a memory pillar adjacent to the one of the second portions in the third direction among the memory pillars, a length of the first conductor layer in the third direction is shorter than a length of the second conductor layer in the third direction.

3. The device of claim 1, wherein
each of the second portions includes a first sub-portion and a second sub-portion provided below the first sub-portion and including the lower surface of each of the second portions, and
the second sub-portion has a tapered shape in which a width of the second sub-portion in the third direction increases from a lower side to an upper side.

4. The device of claim 3, wherein the first sub-portion is provided above upper surfaces of the memory pillars.

5. The device of claim 3, wherein
the first sub-portion has a width wider than an upper end of the second sub-portion in the third direction, and
each of the second portions has a stepped structure formed by the first sub-portion and the second sub-portion on each of one end side and the other end side in the third direction.

6. The device of claim 1, wherein each of the second portions overlaps at least one of the memory pillars when viewed from above.

7. The device of claim 6, wherein each of the second portions is separated from the memory pillars.

8. The device of claim 6, wherein at least one of the second portions is in contact with an upper end portion of at least one of the memory pillars.

9. The device of claim 1, wherein each of the second portions does not overlap the memory pillars when viewed from above.

10. The device of claim 1, wherein a width of the lower surface of each of the second portions in the third direction is equal to or larger than a width of the first portion in the third direction.

11. A semiconductor memory device, comprising:
a plurality of conductor layers provided apart from each other in a first direction perpendicular to a substrate surface;
a plurality of memory pillars penetrating the conductor layers and extending in the first direction; and
a member that includes a first portion extending in a second direction in the substrate surface in the conductor layers and a plurality of second portions provided apart from each other in the second direction on an upper layer side of the conductor layers, and divides the conductor layers in a third direction orthogonal to the second direction in the substrate surface, wherein
at least one of the second portions overlaps a first memory pillar of the memory pillars when viewed from above, and
the at least one of the second portions is in contact with an upper end portion of the first memory pillar.

12. The device of claim 11, wherein a lower surface of each of the second portions is located below an upper surface of a first conductor layer included in an uppermost layer of the conductor layers.

13. The device of claim 12, wherein the lower surface of each of the second portions is located above an upper surface of a second conductor layer different from the first conductor layer among the conductor layers, and
the second conductor layer is coupled to a gate of a memory cell included in an uppermost layer among a plurality of memory cells included in each of the memory pillars.

14. The device of claim 12, wherein
the lower surface of each of the second portions is located at a height equal to or lower than an upper surface of a second conductor layer different from the first conductor layer among the conductor layers, and
the upper end portion of the first memory pillar is included above the upper surface of the second conductor layer, and
the second conductor layer is coupled to a gate of a memory cell included in an uppermost layer among a plurality of memory cells included in each of the memory pillars.

15. The device of claim 11, wherein a lower surface of each of the second portions is located at a height equal to or higher than an upper surface of a first conductor layer included in an uppermost layer of the conductor layers.

16. The device of claim 11, further comprising:
a plurality of upper layer wirings each extending in the third direction; and
a first contact that electrically couples the first memory pillar to one of the upper layer wirings, wherein
the first contact is in contact with the at least one of the second portions.

17. A semiconductor memory device, comprising:
a plurality of conductor layers provided apart from each other in a first direction perpendicular to a substrate surface;
a plurality of memory pillars penetrating the conductor layers and extending in the first direction; and
a member that includes a first portion extending in a second direction in the substrate surface in the conductor layers and a plurality of second portions provided apart from each other in the second direction on an upper layer side of the conductor layers, and divides the conductor layers in a third direction orthogonal to the second direction in the substrate surface, wherein
each of the second portions includes a first sub-portion having a first width in the second direction and a second sub-portion provided below the first sub-portion and having a second width narrower than the first width in the second direction, and
each of the second portions has a stepped structure formed by the first sub-portion and the second sub-portion on each of one end side and the other end side in the second direction.

18. The device of claim 17, wherein
the first sub-portion has a third width in the third direction, and the second sub-portion has a fourth width narrower than the third width in the third direction, and
each of the second portions has a stepped structure formed by the first sub-portion and the second sub-portion on each of one end side and the other end side in the third direction.

19. The device of claim 17, wherein a lower surface of each of the second portions is located below an upper surface of a first conductor layer included in an uppermost layer of the conductor layers.

20. The device of claim 17, wherein a lower surface of each of the second portions is located at a height equal to or higher than an upper surface of a first conductor layer included in an uppermost layer of the conductor layers.
